(19) United States
(12) Patent Application Publication
(10) Pub. No.: US 2026/0123135 A1
(43) Pub. Date: Apr. 30, 2026

(54) DISPLAY DEVICE AND ELECTRONIC APPARATUS INCLUDING THE SAME

(71) Applicant: Samsung Display Co., LTD., Yongin-si (KR)

(72) Inventors: Changil TAE, Yongin-si (KR); Gyujeong LEE, Yongin-si (KR); Hyungil JEON, Yongin-si (KR)

(21) Appl. No.: 19/375,371

(22) Filed: Oct. 31, 2025

(30) Foreign Application Priority Data
Oct. 31, 2024 (KR) 10-2024-0152963

(51) Int. Cl. H10H 29/39; H10H 29/49

(52) U.S. Cl. CPC H10H 29/39; H10H 29/49

(57) ABSTRACT

A display device includes: a first-1 electrode pad, a first-2 electrode pad, a second electrode pad spaced apart from the first-1 and first-2 electrode pads and including a first portion, a second portion adjacent to the first portion in a first direction, and a connection portion connecting the first portion and the second portion, a first light-emitting element connected to the first-1 electrode pad through a first bump metal and connected to the first portion of the second electrode pad through a second bump metal, and a second light-emitting element connected to the first-2 electrode pad through a third bump metal and connected to the second portion of the second electrode pad through the second bump metal. A width of the connection portion in a second direction crossing the first direction is less than a width of the first portion in the second direction.

This application claims priority to Korean Patent Application No. 10-2024-0152963, filed on Oct. 31, 2024, and all the benefits accruing therefrom under 35 U.S.C. § 119, the content of which in its entirety is herein incorporated by reference.

### BACKGROUND

### 1. Field

One or more embodiments relate to a display device (e.g., a flexible display device) and an electronic apparatus including the display device.

### 2. Description of the Related Art

According to the development of display devices visually displaying electrical signals, various display devices having excellent characteristics, such as reduced thickness, reduced weight, and low power consumption, have been introduced. For example, flexible display devices that can be folded or rolled into a roll shape have been introduced. Recently, research and development on display devices having various structures, such as stretchable display devices that can be changed into various shapes, have been actively conducted.

### SUMMARY

One or more embodiments include a display device, for example, a flexible display device.

Additional aspects will be set forth in part in the description which follows and, in part, will be apparent from the description, or may be learned by practice of the presented embodiments of the disclosure.

According to one or more embodiments, a display device includes a first-1 electrode pad and a first-2 electrode pad, spaced apart from each other in a first direction, a second electrode pad spaced apart from the first-1 electrode pad and the first-2 electrode pad in a second direction crossing the first direction, the second electrode pad including a first portion, a second portion adjacent to the first portion in the first direction, and a first connection portion connecting the first portion and the second portion to each other, a first light-emitting element electrically connected to the first-1 electrode pad through a first bump metal and electrically connected to the first portion of the second electrode pad through a second bump metal, and a second light-emitting element electrically connected to the first-2 electrode pad through a third bump metal and electrically connected to the second portion of the second electrode pad through the second bump metal, and a width of the first connection portion of the second electrode pad in the second direction is less than a width of the first portion of the second electrode pad in the second direction.

The display device may further include a common voltage line electrically connected to the second electrode pad and an insulating layer between the second electrode pad and the common voltage line, and the first connection portion of the second electrode pad may be electrically connected to the common voltage line through a contact hole in the insulating layer.

A width of the first portion of the second electrode pad in the first direction may be substantially equal to a width of the first-1 electrode pad in the first direction.

The first portion of the second electrode pad may include a first-1 portion relatively adjacent to the first-1 electrode pad and a first-2 portion relatively far from the first-1 electrode pad, and a width of the first-1 portion in the first direction may be less than a width of the first-2 portion in the first direction.

A width of the second portion of the second electrode pad in the first direction may be greater than the width of the first-1 portion of the first portion of the second electrode pad in the first direction.

The second portion of the second electrode pad may include a second-1 portion relatively adjacent to the first-2 electrode pad and a second-2 portion relatively far from the first-2 electrode pad, and a width of the second-1 portion in the first direction may be less than a width of the second-2 portion in the first direction.

A width of a first portion of the first-1 electrode pad, which is relatively adjacent to the first portion of the second electrode pad, in the first direction may be less than a width of a second portion of the first-1 electrode pad, which is relatively far from the first portion of the second electrode pad in the first direction.

The width of the first portion of the first-1 electrode pad may be substantially equal to the width of the first-1 portion of the first portion of the second electrode pad, in the first direction.

The second bump metal may include gold, nickel, or indium.

Each of the first bump metal and the third bump metal may include the same material as the second bump metal.

According to one or more embodiments, a display device includes a display area and a non-display area outside the display area, the display device including a first island portion positioned in the display area, a first bridge portion connecting the first island portion and another first island portion adjacent to the first island portion to each other, first electrode pads disposed in the first island portion and spaced apart from each other in a first direction, a second electrode pad disposed in the first island portion and spaced apart from the first electrode pads in a second direction crossing the first direction, the second electrode pad including a first portion, a second portion, and a third portion, spaced apart from each other in the first direction, a first connection portion connecting the first portion and the second portion to each other, and a second connection portion connecting the second portion and the third portion to each other, and light-emitting elements electrically connected to the first electrode pads, respectively, and the first to third portions of the second electrode pad, respectively, where a width of the first connection portion in the second direction and a width of the second connection portion in the second direction are each less than a width of the second portion of the second electrode pad in the second direction.

The display device may further include a common voltage line electrically connected to the second electrode pad, and a connection point of the second electrode pad and the common voltage line may correspond to at least one of the first connection portion and the second connection portion of the second electrode pad.

The first portion of the second electrode pad may include a first-1 portion relatively adjacent to the first electrode pads and a first-2 portion relatively far from the first electrode pads, and a width of the first-1 portion in the first direction may be less than a width of the first-2 portion in the first direction.

A width of the second portion of the second electrode pad in the first direction may be greater than the width of the first-1 portion of the first portion of the second electrode pad in the first direction.

The second portion of the second electrode pad may include a second-1 portion relatively adjacent to the first electrode pads and a second-2 portion relatively far from the first electrode pads, and a width of the second-1 portion in the first direction may be less than a width of the second-2 portion in the first direction.

A first electrode pad among the first electrode pads, which is adjacent to the first portion of the second electrode pad, may include a portion relatively adjacent to the first portion of the second electrode pad and a portion relatively far from the first portion of the second electrode pad, and a width of the portion relatively adjacent to the first portion of the second electrode pad in the first direction may be less than a width of the portion relatively far from the first portion of the second electrode pad in the first direction.

The second bump metal may include gold, nickel, or indium.

According to one or more embodiments, an electronic apparatus includes a display device, the display device including a first-1 electrode pad and a first-2 electrode pad, spaced apart from each other in a first direction, a second electrode pad spaced apart from the first-1 electrode pad and the first-2 electrode pad in a second direction crossing the first direction and comprising a first portion, a second portion adjacent to the first portion in the first direction, and a first connection portion connecting the first portion and the second portion to each other, a first light-emitting element electrically connected to the first-1 electrode pad through a first bump metal and electrically connected to the first portion of the second electrode pad through a second bump metal, and a second light-emitting element electrically connected to the first-2 electrode pad through a third bump metal and electrically connected to the second portion of the second electrode pad through the second bump metal, where a width of the first connection portion of the second electrode pad in the second direction is less than a width of the first portion of the second electrode pad in the second direction.

The display device may further include a common voltage line electrically connected to the second electrode pad and an insulating layer between the second electrode pad and the common voltage line, and the first connection portion of the second electrode pad may be electrically connected to the common voltage line through a contact hole in the insulating layer.

Each of the first bump metal, the second bump metal, and the third bump metal may include gold, nickel, or indium.

According to one or more embodiments, an electronic apparatus including a display section includes the display device described above. The display device corresponds to the display section of the electronic apparatus, and the electronic apparatus includes a frame accommodating the display device therein and a stroke accommodated in the frame and disposed below the display device.

The display section may be three-dimensionally stretchable.

The display section may be three-dimensionally stretched by a movement of the stroke.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment;

FIGS. 2A and 2B are perspective views each illustrating a state in which the display device of FIG. 1 is stretched in a first direction;

FIG. 2C is a perspective view illustrating a state in which the display device of FIG. 1 is stretched in a second direction;

FIG. 2D is a perspective view illustrating a state in which the display device of FIG. 1 is stretched in the first direction and the second direction;

FIG. 2E is a perspective view illustrating a state in which the display device of FIG. 1 is stretched in a third direction;

FIG. 3 is a schematic plan view of a display device according to an embodiment;

FIG. 4A is an enlarged plan view of a region IV of FIG. 3 as a portion of the display device of FIG. 3, according to an embodiment;

FIG. 4B is an enlarged plan view of the region IV of FIG. 3 as a portion of the display device of FIG. 3, according to an embodiment;

FIG. 4C is an enlarged plan view of the region IV of FIG. 3 as a portion of the display device of FIG. 3, according to an embodiment;

FIG. 5 is a schematic cross-sectional view of a first island portion and a first bridge portion, which are disposed in a display area of a display device according to an embodiment;

FIGS. 6A to 6C are equivalent circuit diagrams each illustrating a sub-pixel of a display device according to an embodiment;

FIG. 7 is a schematic plan view of a first island portion of a display device according to an embodiment;

FIG. 8 is a cross-sectional view of the first island portion of the display device according to an embodiment, taken along lines VIIIa-VIIIa′ and VIIIb-VIIIb′ of FIG. 7;

FIG. 9 is a plan view showing excerpts of first and second electrode pads and light-emitting diodes, which are disposed in a first island portion of a display device according to an embodiment;

FIG. 10 is a plan view showing excerpts of first and second electrode pads and light-emitting diodes, which are disposed in a first island portion of a display device according to another embodiment;

FIG. 11 is a plan view showing excerpts of first and second electrode pads and light-emitting diodes, which are disposed in a first island portion of a display device according to still another embodiment;

FIG. 12 is a plan view showing excerpts of first and second electrode pads and light-emitting diodes, which are disposed in a first island portion of a display device according to yet another embodiment; and

FIGS. 13A to 13G are schematic perspective views showing embodiments of an electronic apparatus including a display device, respectively.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” “first-1”, “first-2”, “second-1”, “second-2”, etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.” “About” or “substantially the same/equal” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially equal” can mean within one or more standard deviations, or within ±10%, 5% or 2% of the stated value.

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

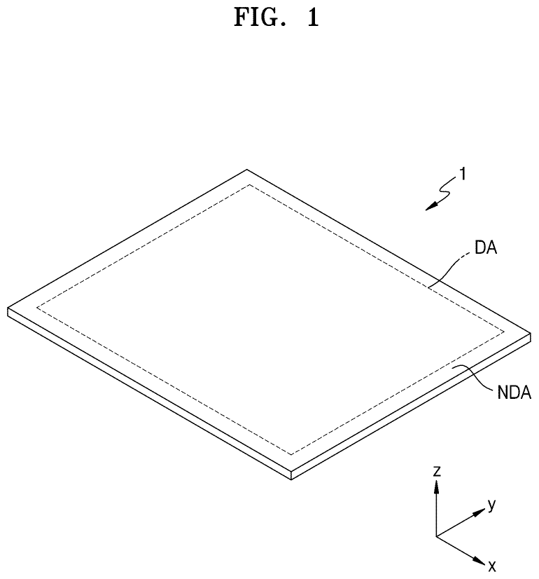

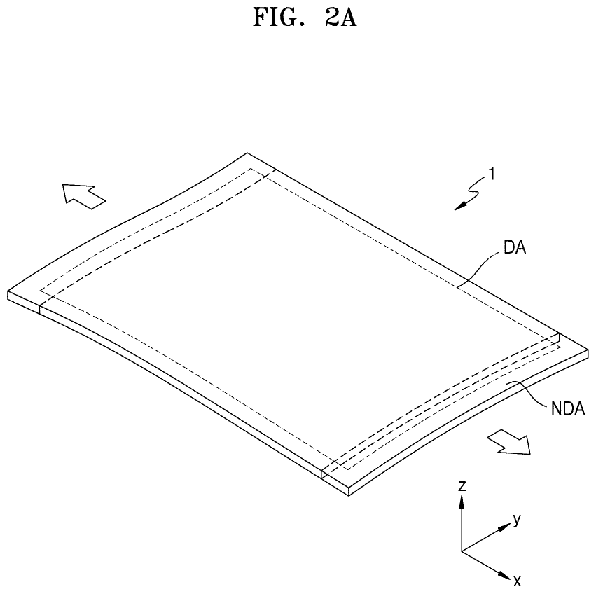

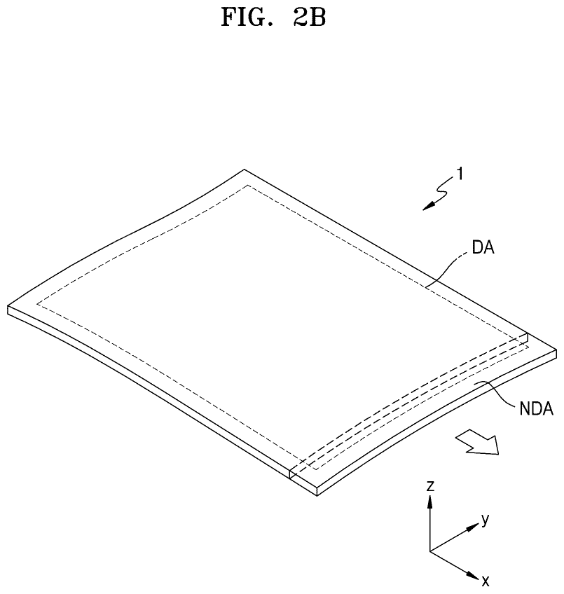

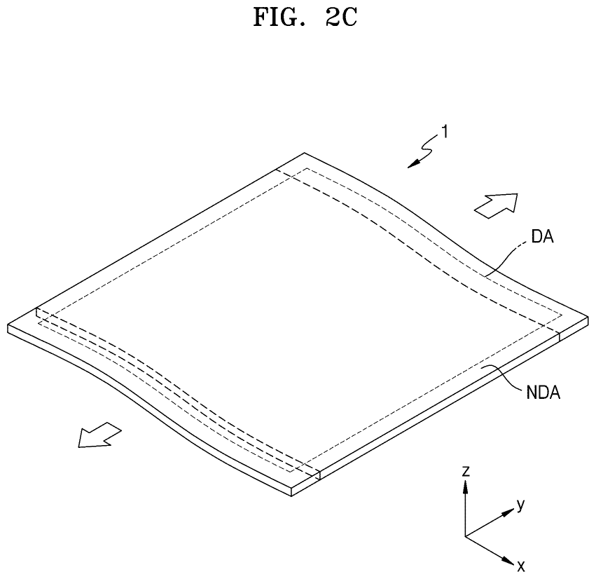

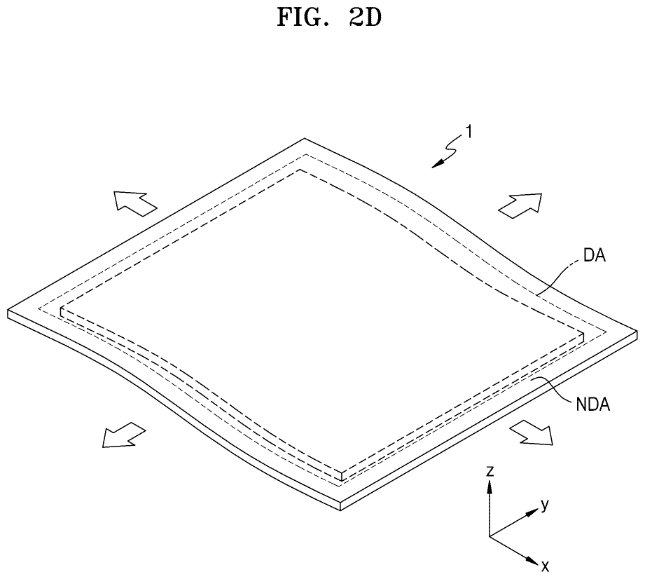

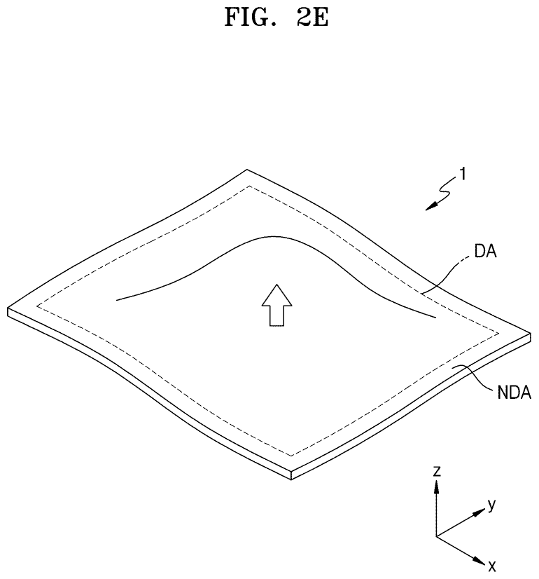

FIG. 1 is a schematic perspective view of a display device 1 according to an embodiment. FIGS. 2A and 2B are perspective views each illustrating a state in which the display device 1 of FIG. 1 is stretched in a first direction. FIG. 2C is a perspective view illustrating a state in which the display device 1 of FIG. 1 is stretched in a second direction. FIG. 2D is a perspective view illustrating a state in which the display device 1 of FIG. 1 is stretched in the first direction and the second direction. FIG. 2E is a perspective view illustrating a state in which the display device 1 of FIG. 1 is stretched in a third direction.

Referring to FIG. 1, the display device 1 may include a display area DA and a non-display area NDA. The display area DA may include a plurality of pixels. The display device 1 may provide an image by using light emitted by the plurality of pixels. The non-display area NDA may be disposed outside the display area DA. The non-display area NDA is an area in which the pixels are not disposed, and may entirely surround the display area DA.

The display device 1 may be stretched or shrunk in various directions. The display device 1 may be stretched in the first direction (e.g., an x direction and/or an −x direction) by an external force applied by an external object or a user. In an embodiment, as shown in FIGS. 2A and 2B, the display area DA and/or the non-display area NDA of the display device 1 may be stretched in the first direction (e.g., the x direction and/or the −x direction). For example, as shown in FIG. 2A, the display device 1 may be stretched in the x direction and the −x direction, or the display device 1 may be stretched in the x direction in a state in which one side of the display device 1 is fixed, as shown in FIG. 2B.

The display device 1 may be stretched in the second direction (e.g., a y direction and/or a −y direction) by an external force applied by an external object or a user. In an embodiment, as shown in FIG. 2C, the display area DA and/or the non-display area NDA of the display device 1 may be stretched in the y direction and the −y direction. In another embodiment, the display device 1 may be stretched in the y direction or the −y direction in a state in which one side of the display device 1 is fixed.

The display device 1 may be stretched in a plurality of directions, for example, the first direction (e.g., the x direction and/or the −x direction) and the second direction (e.g., the y direction and/or the −y direction), by an external force applied by an external object or a part of a human's body. As shown in FIG. 2D, the display area DA and/or the non-display area NDA of the display device 1 may be stretched in the ±x direction and the ±y direction.

The display device 1 may be stretched in the third direction (e.g., a z direction or a −z direction) by an external force applied by an external object or a part of a human's body. In an embodiment, FIG. 2E shows that a portion of the display device 1, for example, a partial area of the display area DA, protrudes in the z direction. In another embodiment, a portion of the display device 1, for example, a partial area of the display area DA, may protrude in the −z direction (or may be depressed in the z direction).

FIGS. 2A to 2E show that the display device 1 is stretched in the first direction, the second direction, and/or the third direction, but the disclosure is not limited thereto. In another embodiment, the display device 1 may be variously modified into irregular shapes, such as having two or more axes and being bent or twisted.

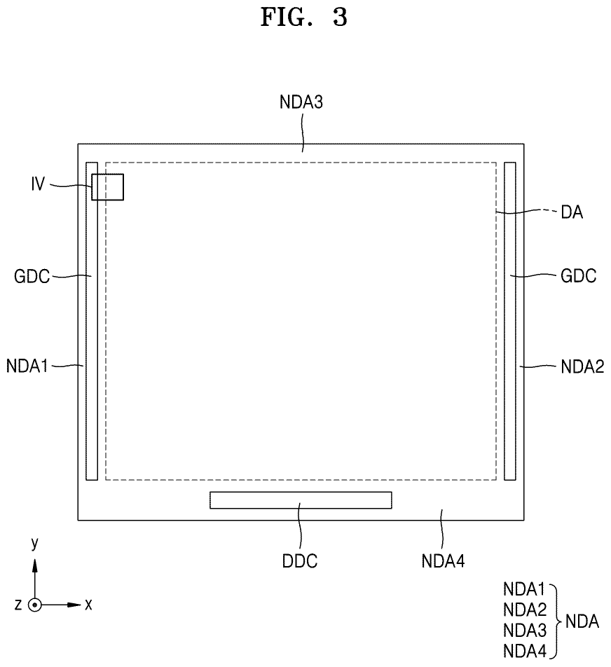

FIG. 3 is a schematic plan view of the display device 1 (refer to FIG. 1) according to an embodiment.

A plurality of pixels may be disposed in the display area DA of the display device 1. Each of the plurality of pixels may include sub-pixels emitting different colors of light. A light-emitting element corresponding to each sub-pixel may be disposed in the display area DA. A circuit configured to provide electrical signals to the light-emitting elements disposed in the display area DA and transistors electrically connected to the light-emitting elements may be positioned in the non-display area NDA surrounding the display area DA. Gate driving circuits GDC may be disposed in a first non-display area NDA1 and a second non-display area NDA2, respectively, where the first non-display area NDA1 and the second non-display area NDA2 are disposed on both sides of the display device 1 with the display area DA therebetween. A gate driving circuit GDC may include drivers configured to provide electrical signals to a gate electrode of each of the transistors electrically connected to the light-emitting elements. FIG. 3 shows that the gate driving circuit GDC is disposed in each of the first non-display area NDA1 and the second non-display area NDA2, but the disclosure is not limited thereto. In another embodiment, the gate driving circuit GDC may be disposed in any one of the first non-display area NDA1 and the second non-display area NDA2.

A data driving circuit DDC may be disposed in a third non-display area NDA3 and/or a fourth non-display area NDA4, which connects the first non-display area NDA1 to the second non-display area NDA2. In an embodiment, FIG. 3 shows that the data driving circuit DDC is disposed in the fourth non-display area NDA4. In another embodiment, the data driving circuit DDC may be disposed in each of the third non-display area NDA3 and the fourth non-display area NDA4.

FIG. 3 shows that the data driving circuit DDC is disposed in the fourth non-display area NDA4 of the display device 1, but the disclosure is not limited thereto. In another embodiment, the display device 1 may further include a flexible circuit board (not shown) electrically connected to a terminal portion (not shown) disposed in the fourth non-display area NDA4, and the data driving circuit DDC may be disposed on the flexible circuit board described above.

In some embodiments, the elongation of the non-display area NDA may be equal to or less than the elongation of the display area DA. In an embodiment, the non-display area NDA may have a different elongation for each area. For example, the first non-display area NDA1, the second non-display area NDA2, and the third non-display area NDA3 may have substantially the same elongation, but the elongation of the fourth non-display area NDA4 may be less than the elongation of each of the first non-display area NDA1, the second non-display area NDA2, and the third non-display area NDA3. In the disclosure, an elongation is a numerical value that represents a change in length (ΔL/L) by which the display device 1 may extend without physical damage to the display device 1 when an external force is applied to the display device 1. Herein, ΔL is a change in length of a display device, and L represents an initial length of the display device.

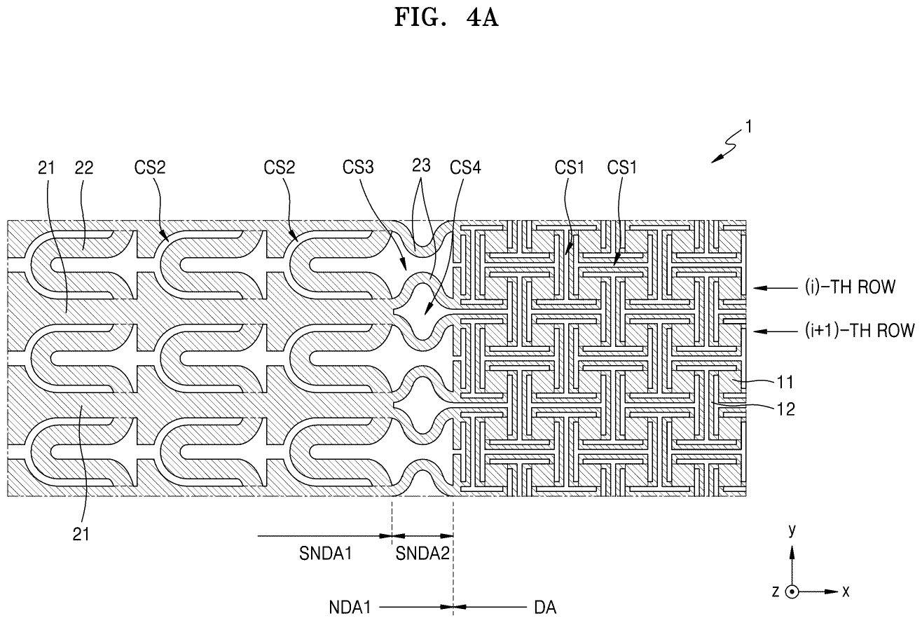

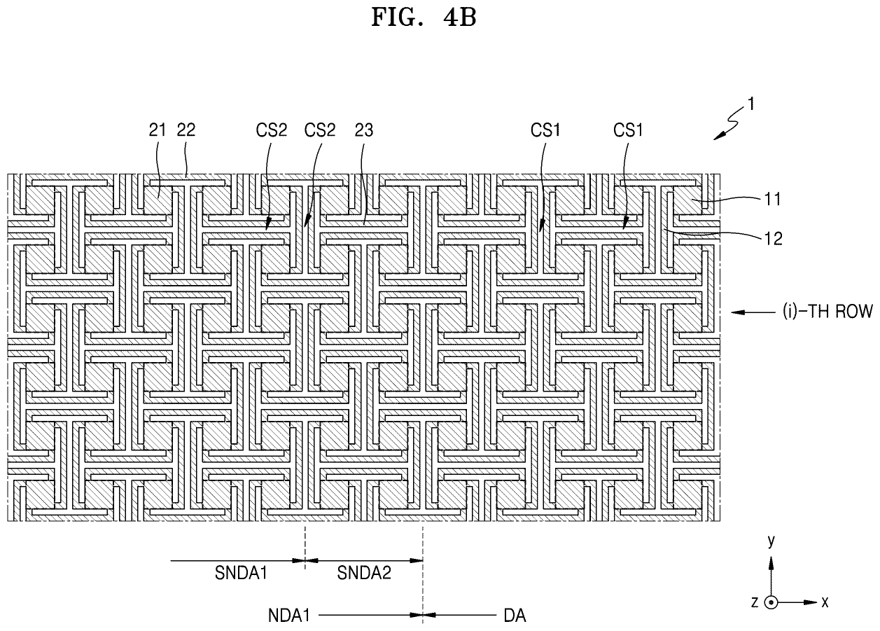

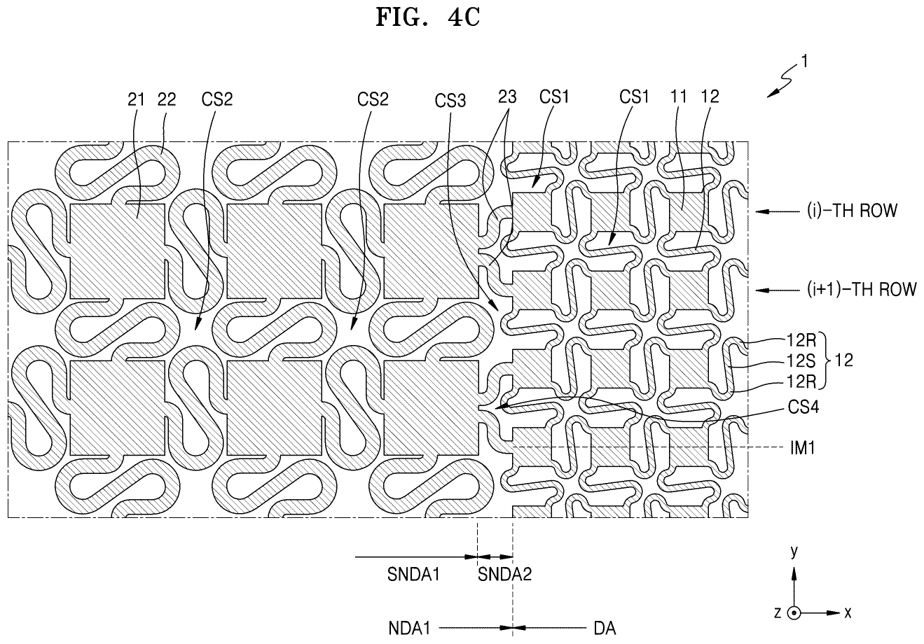

FIG. 4A is an enlarged plan view of a region IV of FIG. 3 as a portion of the display device 1 according to an embodiment.

Referring to FIG. 4A, the display device 1 may include, in the display area DA, first island portions 11 spaced apart from each other in the first direction (e.g., the x direction or the −x direction) and the second direction (e.g., the y direction or the −y direction), and first bridge portions 12 connecting adjacent first island portions 11 to each other.

Each first island portion 11 may be connected to a plurality of first bridge portions 12. For example, each first island portion 11 may be connected to four first bridge portions 12. Two first bridge portions 12 may be disposed on opposite sides of the first island portion 11 in the first direction (e.g., the x direction or the −x direction), respectively, and the remaining two first bridge portions 12 may be disposed on opposite sides of the first island portion 11 in the second direction (e.g., the y direction or the −y direction), respectively. In an embodiment, the four first bridge portions 12 may be connected to four sides of the first island portion 11, respectively. Each of the four first bridge portions 12 may be adjacent to each of corners of the first island portion 11.

The first bridge portions 12 may be spaced apart from each other by a first opening portion CS1 positioned between the first bridge portions 12. In an embodiment, a first opening portion CS1 having an approximately H shape and a first opening portion CS1 having an approximately I shape obtained by rotating the above described H shape by 90 degrees may be alternately and repeatedly arranged in each of the first direction (e.g., the x direction or the −x direction) and the second direction (e.g., the y direction or the −y direction). Both end portions of each first bridge portion 12 are connected to adjacent first island portions 11, respectively, but one side of each first bridge portion 12 may be spaced apart from one side of an adjacent first island portion 11 and/or one side of another first bridge portion 12 by the first opening portion CS1.

The display device 1 may include, in a non-display area, for example, the first non-display area NDA1 shown in FIG. 4A, second island portions 21 spaced apart from each other and second bridge portions 22 connecting adjacent second island portions 21 to each other.

Each second island portion 21 may extend in the first direction (e.g., the x direction or the-x direction). The second island portions 21 may be spaced apart from each other in the second direction (e.g., the y direction or the-y direction) crossing the first direction (e.g., the x direction or the −x direction). Each second island portion 21 may include drivers of the gate driving circuit GDC (refer to FIG. 3) described above with reference to FIG. 3.

A second bridge portion 22 may have a serpentine shape. A length of the second bridge portion 22 may be greater than the shortest distance between adjacent second island portions 21 in the second direction (e.g., the y direction or the-y direction). In an embodiment, the second bridge portion 22 may have an approximately omega (Ω) shape that is convex toward the first direction (e.g., the x direction or the −x direction). The second bridge portions 22 may be disposed between adjacent second island portions 21 and may be spaced apart from each other.

The second bridge portions 22 between adjacent second island portions 21 may be spaced apart from each other by a second opening portion CS2. Second opening portions CS2 and the second bridge portions 22 may be alternately arranged in the first direction (e.g., the x direction or the-x direction) between adjacent second island portions 21. The second opening portions CS2 may have the same shape. Both two end portions of each second bridge portion 22 are connected to adjacent second island portions 21, respectively, but one side of each second bridge portion 22 may be spaced apart from one side of an adjacent second island portion 21 and/or one side of another second bridge portion 22 by the second opening portion CS2.

Any one second island portion 21 disposed in the first non-display area NDA1 may correspond to the first island portions 11 of a plurality of rows arranged in the display area DA. For example, any one second island portion 21 disposed in the first non-display area NDA1 may correspond to the first island portions 11 arranged in an (i)-th row and the first island portions 11 arranged in an (i+1)-th row in the display area DA (where i is a positive number greater than 0). FIG. 4A shows that one second island portion 21 corresponds to two rows of first island portions 11, but the disclosure is not limited thereto. In another embodiment, any one second island portion 21 disposed in the first non-display area NDA1 may correspond to n rows of first island portions 11 disposed in the display area DA (where n is a positive number of 3 or more).

The non-display area, for example, the first non-display area NDA1, may include a first sub-non-display area SNDA1 in which the second island portions 21 and the second bridge portions 22 described above are disposed, and a second sub-non-display area SNDA2 between the first sub-non-display area SNDA1 and the display area DA. Third bridge portions 23 connecting the display area DA and the first sub-non-display area SNDA1 to each other may be disposed in the second sub-non-display area SNDA2. One end portion of a third bridge portion 23 may be connected to the second island portion 21 and/or the second bridge portion 22, and the other end portion of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as shown in FIG. 4A, the third bridge portion 23 may have an approximately omega (Ω) shape that is convex toward the second direction (e.g., the y direction or the −y direction). Adjacent third bridge portions 23 arranged in the second direction (e.g., the y direction or the −y direction) may have structures that are symmetrical to each other, for example, one of the adjacent third bridge portions 23 arranged in the second direction (e.g., the y direction or the −y direction) may be convex in the y direction, and the other one may be convex in the −y direction). A structure in which third opening portions CS3 and fourth opening portions CS4, which have different shapes, are repeated may be provided between the third bridge portions 23. A width of the third bridge portion 23 may be different from a width of the first bridge portion 12 and a width of the second bridge portion 22. In an embodiment, the width of the third bridge portion 23 may be greater than the width of the first bridge portion 12 and may be less than the width of the second bridge portion 22.

FIG. 4A shows that the second island portion 21 and the second bridge portion 22 in the non-display area (e.g., the first non-display area NDA1) have different shapes from the first island portion 11 and the first bridge portion 12 in the display area DA, respectively. In another embodiment, the second island portion 21 and the second bridge portion 22 in the non-display area may have the same shapes as the first island portion 11 and the first bridge portion 12 in the display area DA, respectively.

FIG. 4B is an enlarged view of the region IV of FIG. 3 as a portion of the display device 1 according to an embodiment.

Referring to FIG. 4B, the display device 1 may include, in the display area DA, the first island portions 11 spaced apart from each other and the first bridge portions 12 spaced apart from each other by the first opening portion CS1 and connecting adjacent first island portions 11 to each other. The structure of the display area DA of FIG. 4B may be the same as the structure of the display area DA described above with reference to FIG. 4A.

The display device 1 may include the second island portions 21 and the second bridge portions 22, which are disposed in the non-display area, for example, the first non-display area NDA1. In an embodiment, the second island portions 21 and the second bridge portions 22 may have substantially the same shapes as the first island portions 11 and the first bridge portions 12, respectively.

The second island portions 21 may be spaced apart from each other in the first direction (e.g., the x direction or the −x direction) and the second direction (e.g., the y direction or the −y direction) in the non-display area, for example, the first non-display area NDA1. The second bridge portions 22 may be connected to adjacent second island portions 21, respectively. The second bridge portions 22 may be spaced apart from each other by the second opening portion CS2 positioned between the second bridge portions 22.

The second opening portion CS2 may have substantially the same shape as the first opening portion CS1. For example, a second opening portion CS2 having an approximately H shape and a second opening portion CS2 having an approximately I shape may be alternately and repeatedly arranged in the non-display area, for example, the first non-display area NDA1. Both two end portions of each second bridge portion 22 are connected to adjacent second island portions 21, respectively, but one side of each second bridge portion 22 may be spaced apart from one side of an adjacent second island portion 21 and/or one side of another second bridge portion 22 by the second opening portion CS2.

Each second island portion 21 may be connected to four second bridge portions 22. Each second island portion 21 may include drivers of the gate driving circuit GDC (refer to FIG. 3) described above with reference to FIG. 3.

The second island portions 21 of any one row disposed in the first non-display area NDA1 may correspond to the first island portions 11 of any one row arranged in the display area DA. For example, the second island portions 21 arranged in an (i)-th row in the first direction (e.g., the x direction or the-x direction) in the first non-display area NDA1 may correspond to the first island portions 11 arranged in the same row in the display area DA, for example, the (i)-th row (where i is a positive number greater than 0).

The display device 1 may include the third bridge portions 23 disposed in the second sub-non-display area SNDA2 connecting the display area DA and the first sub-non-display area SNDA1 to each other. The non-display area, for example, the first non-display area NDA1, may include the first sub-non-display area SNDA1 in which the second island portions 21 and the second bridge portions 22 are disposed, and the second sub-non-display area SNDA2 including the third bridge portions 23 and positioned between the first sub-non-display area SNDA1 and the display area DA. The third bridge portion 23 may be substantially the same as the first bridge portion 12 and the second bridge portion 22. For example, the width of the third bridge portion 23 may be equal to the width of the first bridge portion 12 and the width of the second bridge portion 22.

FIG. 4C is an enlarged plan view of the region IV of FIG. 3 as a portion of the display device of FIG. 3, according to an embodiment.

Referring to FIG. 4C, the display device 1 may include, in the display area DA, the first island portions 11 spaced apart from each other in the first direction (e.g., the x direction or the −x direction) and the second direction (e.g., the y direction or the −y direction), and the first bridge portions 12 connecting adjacent first island portions 11 to each other.

The first bridge portions 12 may be disposed to be spaced apart from each other by the first opening portion CS1 positioned between the first bridge portions 12. The first bridge portion 12 may have a serpentine shape. For example, as shown in FIG. 4C, the first bridge portion 12 may have an approximate shape of ‘the letter S’, for example, a shape including two round portions 12R and a straight-line portion 12S between the two round portions 12R.

Each first island portion 11 may be connected to a plurality of first bridge portions 12. For example, each first island portion 11 may be connected to four first bridge portions 12. Two first bridge portions 12 may be disposed on opposite sides of the first island portion 11 in the first direction (e.g., the x direction or the −x direction), respectively, and the remaining two first bridge portions 12 may be disposed on opposite sides of the first island portion 11 in the second direction (e.g., the y direction or the −y direction), respectively. The four first bridge portion 12 may be connected to four sides of the first island portion 11, respectively. Each of the four first bridge portions 12 may be adjacent to each of corners of the first island portion 11.

The display device 1 may include, in the non-display area, for example, the first non-display area NDA1 shown in FIG. 4C, the second island portions 21 spaced apart from each other in the first direction (e.g., the x direction or the-x direction) and the second direction (e.g., the y direction or the-y direction), and the second bridge portions 22 connecting adjacent second island portions 21 to each other.

The second bridge portions 22 may be disposed to be spaced apart from each other by the second opening portion CS2 positioned between the second bridge portions 22. The second bridge portion 22 may have a serpentine shape. For example, as shown in FIG. 4C, the second bridge portion 22 may have an approximate shape of ‘the letter S.’ The size and/or width of the second bridge portion 22 may be different from the size and/or width of the first bridge portion 12. For example, the size and/or width of the second bridge portion 22 may be greater than the size and/or width of the first bridge portion 12. The radius of curvature of a rounded portion of the second bridge portion 22 may be different from the radius of curvature of a rounded portion of the first bridge portion 12. For example, the radius of curvature of the rounded portion of the second bridge portion 22 may be greater than the radius of curvature of the rounded portion of the first bridge portion 12.

Each second island portion 21 may be connected to a plurality of second bridge portions 22. Each second island portion 21 may be connected to four second bridge portions 22. Two second bridge portions 22 may be respectively disposed on opposite sides of the second island portion 21 in the first direction (e.g., the x direction or the-x direction), respectively, and the remaining two second bridge portions 22 may be disposed on opposite sides of the second island portion 21 in the second direction (e.g., the y direction or the-y direction), respectively. In an embodiment, the four second bridge portions 22 may be connected to four sides of the second island portion 21, respectively. Each second bridge portion 22 may be connected to a central portion of each side of the second island portion 21.

The second island portions 21 of any one row disposed in the first non-display area NDA1 may correspond to the first island portions 11 of a plurality of rows arranged in the display area DA. For example, the second island portions 21 of any one row disposed in the first non-display area NDA1 may correspond to the first island portions 11 arranged in the (i)-th row and the first island portions 11 arranged in the (i+1)-th row in the display area DA (where i is a positive number greater than 0). In another embodiment, the second island portions 21 of any one row may correspond to n rows of the first island portions 11 (where n is a positive number of 3 or more).

The non-display area, for example, the first non-display area NDA1, may include the first sub-non-display area SNDA1 in which the second island portions 21 and the second bridge portions 22 described above are disposed, and the second sub-non-display area SNDA2 between the first sub-non-display area SNDA1 and the display area DA. The third bridge portions 23 connecting the display area DA and the first sub-non-display area SNDA1 to each other may be disposed in the second sub-non-display area SNDA2. One end portion of the third bridge portion 23 may be connected to the second island portion 21, and the other end portion of the third bridge portion 23 may be connected to the first island portion 11. For example, one end portion of the third bridge portion 23 may be connected to the central portion of one side of the second island portion 21, and the other end portion of the third bridge portion 23 may be connected to the central portion of one side of the first island portion 11.

The third bridge portion 23 may have a serpentine shape. In an embodiment, the shape of the third bridge portion 23 may be different from the shape of each of the first bridge portion 12 and the second bridge portion 22. A width of the third bridge portion 23 may be different from a width of the first bridge portion 12 and a width of the second bridge portion 22. The width of the third bridge portion 23 may be greater than the width of the first bridge portion 12 and may be less than the width of the second bridge portion 22. The third opening portions CS3 and the fourth opening portions CS4, which have different shapes, may be alternately arranged between the third bridge portions 23 in the second direction (e.g., the y direction or the −y direction).

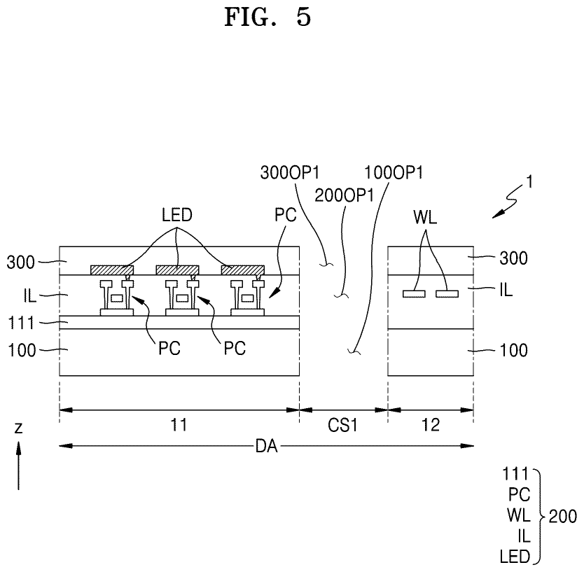

FIG. 5 is a schematic cross-sectional view of the first island portion 11 and the first bridge portion 12, which are disposed in the display area DA of the display device 1 according to an embodiment.

Referring to FIG. 5, the first island portion 11 and the first bridge portion 12, which are disposed in the display area DA, may be spaced apart from each other with the first opening portion CS1 therebetween. The first island portion 11 may include light-emitting elements LED and a circuit electrically connected to the light-emitting elements LED and configured to drive the light-emitting elements LED, for example, a pixel driving circuit unit PC, and the first bridge portion 12 may include a line WL electrically connected to pixel driving circuits PC disposed in adjacent first island portions 11, respectively.

When looking at the first island portion 11, a buffer layer 111 including an inorganic insulating material may be disposed on a substrate 100, and the pixel driving circuit unit PC may be disposed on the buffer layer 111. An insulating layer IL including an inorganic insulating material and/or an organic insulating material may be disposed between the pixel driving circuit unit PC and the light-emitting element LED. The light-emitting element LED may be disposed on the insulating layer IL and may be electrically connected to a corresponding pixel driving circuit unit PC. The light-emitting elements LED may emit light of different colors or the same color. In an embodiment, the light-emitting elements LED may emit red, green, and blue light, respectively. In some embodiments, the light-emitting elements LED may emit white light. In another embodiment, the light-emitting elements LED may emit red, green, blue, and white light, respectively.

The substrate 100 may include a polymer resin, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. In an embodiment, the substrate 100 may be a single layer including the polymer resin described above. In another embodiment, the substrate 100 may have a multi-layered structure including a base layer including the polymer resin described above, and a barrier layer including an inorganic insulating material. The substrate 100 including the polymer resin may be flexible, rollable, or bendable.

In an embodiment, FIG. 5 shows three pixel driving circuits PC disposed in each first island portion 11 and three light-emitting elements LED are connected to each of the pixel driving circuits PC, but the disclosure is not limited thereto. In another embodiment, the number of each of the pixel driving circuits PC and the light-emitting elements LED, which are disposed in the first island portion 11, may be one, two, or four or more.

An encapsulation layer 300 may be disposed on the light-emitting element LED and may protect the light-emitting element LED from external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material, for example, a material such as photoresist.

When looking at the first bridge portion 12, the insulating layer IL including an organic insulating material may be disposed on the substrate 100. When the display device 1 is stretched, the first bridge portion 12, which is relatively transformed, may not include a layer including an inorganic insulating material that is prone to cracks, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a stacked structure different from the stacked structure of the substrate 100 corresponding to the first island portion 11. In some embodiments, the substrate 100 corresponding to the first island portion 11 may have a multi-layered structure including a base layer including a polymer resin and a barrier layer including an inorganic insulating material, and the substrate 100 corresponding to the first bridge portion 12 may have a structure of a polymer resin layer without a layer including an inorganic insulating material.

As described above, lines WL of the first bridge portion 12 may be signal lines (e.g., gate lines, data lines, or the like) for providing electrical signals to transistors included in the pixel driving circuit unit PC of the first island portion 11, or may be voltage lines (e.g., driving voltage lines, initialization voltage lines, or the like) for providing voltages. The encapsulation layer 300 may also be disposed in the first bridge portion 12. In another embodiment, the encapsulation layer 300 may not be present in the first bridge portion 12.

Referring to FIGS. 4A to 4C and 5, the substrate 100 corresponding to the first island portion 11 and the substrate 100 corresponding to the first bridge portion 12 may be connected to each other. In other words, the plan views previously shown in FIGS. 4A to 4C may be substantially the same as the plan view of the substrate 100 of FIG. 5. That is, the substrate 100 may include an area corresponding to the first island portion 11, an area corresponding to the first bridge portion 12, an opening 100OP1 having the same shape as the first opening portion CS1.

Similarly, the encapsulation layer 300 corresponding to the first island portion 11 and the encapsulation layer 300 corresponding to the first bridge portion 12 may be connected to each other. For example, the plan views previously shown in FIGS. 4A to 4C may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening portion CS1.

A circuit-light-emitting element layer 200 between the substrate 100 and the encapsulation layer 300 may include the buffer layer 111, the pixel driving circuit unit PC, the line WL, the insulating layer IL, and the light-emitting element LED. Similar to the substrate 100, the plan views previously shown in FIGS. 4A to 4C may be substantially the same as the plan view of the circuit-light-emitting element layer 200. In other words, the circuit-light-emitting element layer 200 may include an opening 200OP1 having the same shape as the first opening portion CS1.

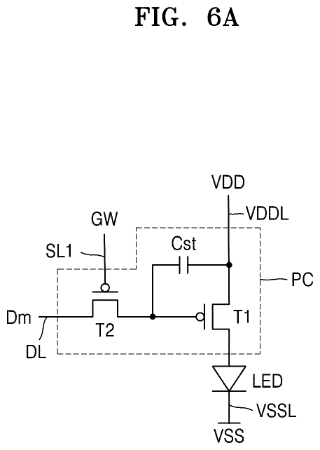

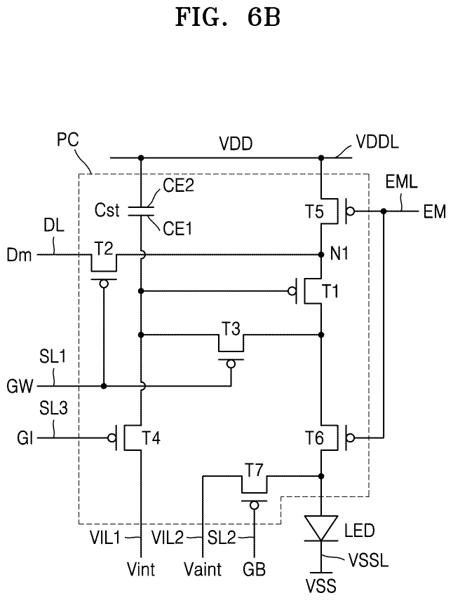

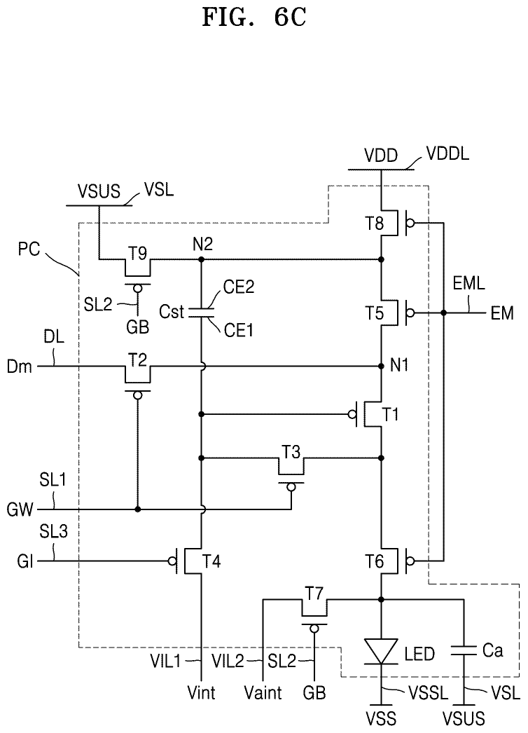

FIGS. 6A to 6C are equivalent circuit diagrams each illustrating a sub-pixel of the display device 1 according to an embodiment.

Referring to FIG. 6A, a light-emitting element LED corresponding to the sub-pixel may be electrically connected to a pixel driving circuit unit PC, and the pixel driving circuit unit PC may include a first transistor T1, a second transistor T2, and a storage capacitor Cst. The pixel driving circuit unit PC may be electrically connected to signal lines and voltage lines. The signal lines may include a gate line, such as a first scan line SL1, and a data line DL, and the voltage lines may include a first voltage line VDDL.

The second transistor T2 may be electrically connected to the first scan line SL1 and the data line DL. The first scan line SL1 may provide a first scan signal GW to a gate electrode of the second transistor T2. The second transistor T2 may be configured to transmit, to the first transistor T1, a data signal Dm input from the data line DL according to the first scan signal GW input from the first scan line SL1.

The storage capacitor Cst may be electrically connected to the second transistor T2 and the first voltage line VDDL, and may store a voltage corresponding to the difference between a voltage received from the second transistor T2 and a first power voltage VDD supplied by the first voltage line VDDL.

The first transistor T1 is a driving transistor, which may control a driving current flowing through the light-emitting element LED. The first transistor T1 may be connected to the first voltage line VDDL and the storage capacitor Cst. The first transistor T1 may control the driving current flowing through the light-emitting element LED from the first voltage line VDDL in accordance to a voltage value stored in the storage capacitor Cst. The light-emitting element LED may emit light having a certain brightness according to the driving current. A first electrode of the light-emitting element LED may be electrically connected to the first transistor T1, and a second electrode thereof may be electrically connected to a second voltage line VSSL providing a second power voltage VSS.

Although FIG. 6A illustrates that the pixel driving circuit unit PC includes two transistors and one storage capacitor, in another embodiment, the pixel driving circuit unit PC may include three or more transistors.

Referring to FIG. 6B, the pixel driving circuit unit PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit unit PC is electrically connected to signal lines and voltage lines. The signal lines may include gate lines, such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may be configured to transmit the first power voltage VDD to the first transistor T1. The first initialization voltage line VIL1 may be configured to transmit, to the pixel driving circuit unit PC, a first initialization voltage Vint initializing the first transistor T1. The second initialization voltage line VIL2 may be configured to transmit, to the pixel driving circuit unit PC, a second initialization voltage Vaint initializing the first electrode of the light-emitting element LED.

The first transistor T1 may be electrically connected to the first voltage line VDDL via the fifth transistor T5 and may be electrically connected to the light-emitting element LED via the sixth transistor T6. The first transistor T1 serves as a driving transistor and receives the data signal Dm in response to a switching operation of the second transistor T2 to supply a driving current to the light-emitting element LED.

The second transistor T2 is a data write transistor, which is electrically connected to the first scan line SL1 and the data line DL. The second transistor T2 is electrically connected to the first voltage line VDDL via the fifth transistor T5. The second transistor T2 is turned on in response to the first scan signal GW received through the first scan line SL1 and performs a switching operation of providing the data signal Dm provided with the data line DL to a first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1.

The fourth transistor T4 is a first initialization transistor, which is electrically connected to the third scan line SL3 and the first initialization voltage line VIL1. The fourth transistor T4 is turned on in response to a third scan signal GI received through the third scan line SL3 to provide the first initialization voltage Vint from the first initialization voltage line VIL1 to a gate electrode of the first transistor T1 to initialize a voltage of the gate electrode of the first transistor T1. The third scan signal GI may correspond to a first scan signal of another pixel driving circuit unit disposed in a previous row of the corresponding pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML and are simultaneously turned on in response to an emission control signal EM received through the emission control line EML to form a current path so that a driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 may be turned on in response to a second scan signal GB received through the second scan line SL2 to provide the second initialization voltage Vaint from the second initialization voltage line VIL2 to the first electrode of the light-emitting element LED to initialize the first electrode of the light-emitting element LED.

The storage capacitor Cst may include the first electrode CE1 and the second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to the difference between voltages of both ends of the first voltage line VDDL and the gate electrode of the first transistor T1.

Referring to FIG. 6C, the pixel driving circuit unit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit unit PC is electrically connected to signal lines and voltage lines. The signal lines may include gate lines, such as the first scan line SL1, the second scan line SL2, the third scan line SL3, and the emission control line EML, and the data line DL. The voltage lines may include the first and second initialization voltage lines VIL1 and VIL2, a maintenance voltage line VSL, and the first voltage line VDDL.

The first voltage line VDDL may be configured to transmit the first power voltage VDD to the first transistor T1. The first initialization voltage line VIL1 may be configured to transmit, to the pixel driving circuit unit PC, the first initialization voltage Vint initializing the first transistor T1. The second initialization voltage line VIL2 may be configured to transmit, to the pixel driving circuit unit PC, the second initialization voltage Vaint initializing the first electrode of the light-emitting element LED. The maintenance voltage line VSL may provide a maintenance voltage VSUS to a second node N2, for example, the second electrode CE2 of the storage capacitor Cst, during an initialization section and a data write section.

The first transistor T1 may be electrically connected to the first voltage line VDDL via the fifth transistor T5 and the eighth transistor T8, and may be electrically connected to the light-emitting element LED via the sixth transistor T6. The first transistor T1 may serve as a driving transistor and receive the data signal Dm in response to a switching operation of the second transistor T2 to supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to the first scan signal GW received through the first scan line SL1 and performs a switching operation of transmitting the data signal Dm transmitted through the data line DL to the first node N1.

The third transistor T3 is electrically connected to the first scan line SL1 and is electrically connected to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 is electrically connected to the third scan line SL3 and the first initialization voltage line VIL1 and turned on in response to the third scan signal GI received through the third scan line SL3 to provide the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit unit disposed in a previous row of the corresponding pixel driving circuit unit PC.

The fifth transistor T5, the sixth transistor T6, and the eighth transistor T8 are electrically connected to the emission control line EML and simultaneously turned on in response to the emission control signal EM received through the emission control line EML to form a current path so that the driving current may flow in a direction from the first voltage line VDDL to the light-emitting element LED.

The seventh transistor T7 is a second initialization transistor, which may be electrically connected to the second scan line SL2, the second initialization voltage line VIL2, and the sixth transistor T6. The seventh transistor T7 is turned on in response to the second scan signal GB received through the second scan line SL2 to provide the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the maintenance voltage line VSL. The ninth transistor T9 may be turned on in response to the second scan signal GB received through the second scan line SL2 to provide the maintenance voltage VSUS to the second node N2, for example, the second electrode CE2 of the storage capacitor Cst, during an initialization section and a data write section.

Each of the eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on during the initialization section and the data write section, and the eighth transistor T8 may be turned on and the ninth transistor T9 may be turned off during an emission section. Because the maintenance voltage VSUS is transmitted to the second node N2 during the initialization section and the data write section, the brightness uniformity (for example, long-range uniformity (LRU)) of a display device according to a voltage drop of the first voltage line VDDL may be improved.

The storage capacitor Cst may include the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the maintenance voltage line VSL, and the first electrode of the light-emitting element LED. The auxiliary capacitor Ca may store and maintain a voltage corresponding to a voltage difference between the first electrode of the light-emitting element LED and the maintenance voltage line VSL while the seventh transistor T7 and the ninth transistor T9 are turned on, so that a problem in which black brightness increases when the sixth transistor T6 is turned off may be prevented.

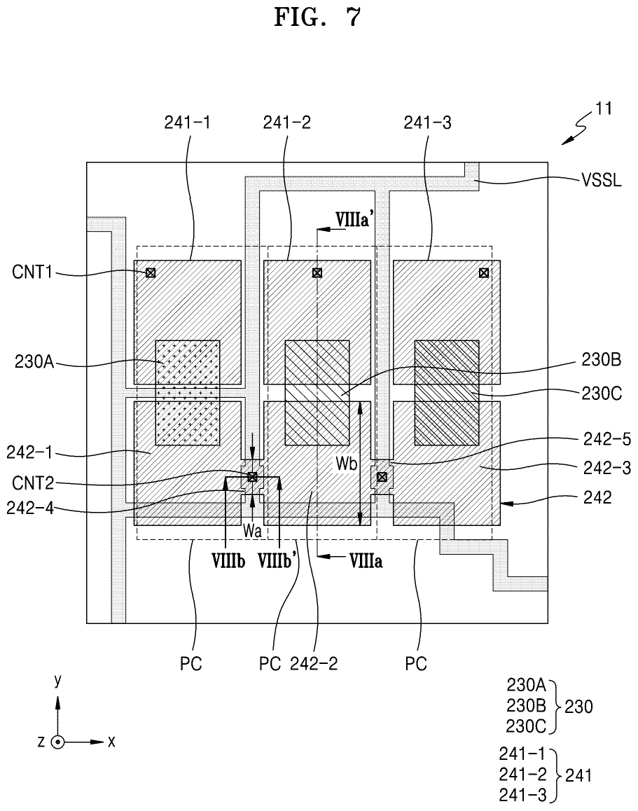

FIG. 7 is a schematic plan view of the first island portion 11 of a display device according to an embodiment.

Referring to FIG. 7, light-emitting elements may be disposed in the first island portion 11. In an embodiment, FIG. 7 illustrates that the light-emitting elements disposed in the first island portion 11 includes first to third light-emitting diodes 230A, 230B, and 230C, which emit light of different colors. For example, one of the first to third light-emitting diodes 230A, 230B, and 230C may emit red light, the other one may emit green light, and the remaining one may emit blue light.

In an embodiment, FIG. 7 illustrates that three light-emitting diodes 230 disposed and three first electrode pads 241 corresponding to the three light-emitting diodes 230, respectively, but the disclosure is not limited thereto. In another embodiment, two or four or more light-emitting diodes 230 may be disposed in the first island portion 11, and two or four or more first electrode pads 241 may be disposed. Hereinafter, for convenience of explanation, a case in which three light-emitting diodes 230 and three first electrode pads 241 are disposed in the first island portion 11 is described.

Each of the light-emitting diodes 230 may be electrically connected to the pixel driving circuit unit PC through a first electrode pad 241 (or a first electrode layer), and may be electrically connected to the second voltage line VSSL, which is a common voltage line, through a second electrode pad 242 (or a second electrode layer).

The first electrode pads 241 may be disposed to be spaced apart from each other in one direction, for example, a first direction (e.g., an x direction or an −x direction). In this regard, FIG. 7 illustrates that the first electrode pads 241 includes a first-1 electrode pad 241-1, a first-2 electrode pad 241-2, and a first-3 electrode pad 241-3. The first-1 electrode pad 241-1, the first-2 electrode pad 241-2, and the first-3 electrode pad 241-3 may be disposed to be spaced apart from each other in the first direction (e.g., the x direction or the −x direction). The first-1 electrode pad 241-1 and the first-3 electrode pad 241-3 may be disposed on opposite sides with the first-2 electrode pad 241-2 therebetween. Each of the first-1 electrode pad 241-1, the first-2 electrode pad 241-2, and the first-3 electrode pad 241-3 may be electrically connected to a corresponding pixel driving circuit unit PC through a first contact hole CNT1.

The second electrode pad 242 may be spaced apart from the first electrode pads 241 in a direction crossing an arrangement direction of the first electrode pads 241, for example, a second direction (e.g., a y direction or a −y direction). The light-emitting elements may share one second electrode pad 242. For example, a first portion 242-1 of the second electrode pad 242 may be electrically connected to the first light-emitting diode 230A, which is a first light-emitting element, a second portion 242-2 of the second electrode pad 242 may be electrically connected to the second light-emitting diode 230B, which is a second light-emitting element, a third portion 242-3 of the second electrode pad 242 may be electrically connected to the third light-emitting diode 230C, which is a third light-emitting element, and the first to third portions 242-1, 242-2, and 242-3 may be integrally connected to each other. The second portion 242-2 of the second electrode pad 242 may be positioned between the first portion 242-1 and the third portion 242-3.

The first portion 242-1 of the second electrode pad 242 may be disposed adjacent to any one first electrode pad 241, for example, the first-1 electrode pad 241-1, in the second direction (for example, the y direction or the −y direction). The second portion 242-2 of the second electrode pad 242 may be disposed adjacent to the other one first electrode pad 241, for example, the first-2 electrode pad 241-2, in the second direction (for example, the y direction or the −y direction). The third portion 242-3 of the second electrode pad 242 may be disposed adjacent to the remaining one first electrode pad 241, for example, the first-3 electrode pad 241-3, in the second direction (for example, the y direction or the −y direction).

The first portion 242-1 and the second portion 242-2 of the second electrode pad 242 may be connected to each other through a first connection portion 242-4, and the second portion 242-2 and the third portion 242-3 of the second electrode pad 242 may be connected to each other through a second connection portion 242-5. A width Wa of each of the first connection portion 242-4 and the second connection portion 242-5 in the second direction (for example, the y direction or the −y direction) may be less than a width Wb of each of the first to third portions 242-1, 242-2, and 242-3 of the second electrode pad 242.

The second electrode pad 242 may be electrically connected to the second voltage line VSSL passing through the first island portion 11 through a second contact hole CNT2. The second voltage line VSSL may include a plurality of branches. One of the branches may pass between the first portion 242-1 and the second portion 242-2 and overlap the first connection portion 242-4, and the other one may pass between the second portion 242-2 and the third portion 242-3 and overlap the second connection portion 242-5. Each of the first connection portion 242-4 and the second connection portion 242-5 may be electrically connected to the second voltage line VSSL through the second contact hole CNT2. FIG. 7 illustrates that each of the first connection portion 242-4 and the second connection portion 242-5 is electrically connected to the second voltage line VSSL through the second contact hole CNT2, but the disclosure is not limited thereto. In an embodiment, at least one of the first connection portion 242-4 and the second connection portion 242-5 may be electrically connected to the second voltage line VSSL through the second contact hole CNT2.

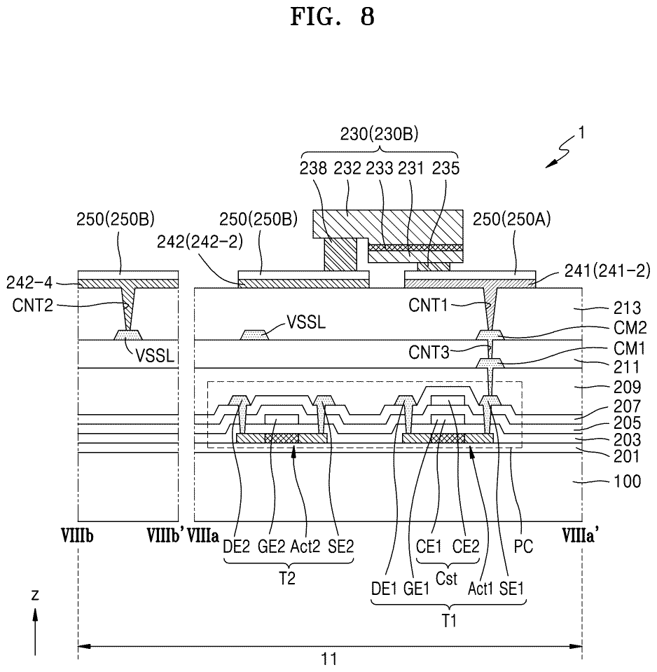

FIG. 8 is a cross-sectional view of the first island portion 11 of the display device 1 according to an embodiment, taken along lines VIIIa-VIIIa′ and VIIIb-VIIIb′ of FIG. 7.

The pixel driving circuit unit PC and a light-emitting diode 230 as a light-emitting element electrically connected to the pixel driving circuit unit PC are disposed on the substrate 100. FIG. 8 illustrates that the light-emitting diode 230 is a second light-emitting diode 230B as an embodiment, but the disclosure is not limited thereto. The structure of the first light-emitting diode 230A and the pixel driving circuit unit PC and the structure of the third light-emitting diode 230C and the pixel driving circuit unit PC are identical to the structure shown in FIG. 8.

The pixel driving circuit unit PC may include transistors and the storage capacitor Cst, which are described above with reference to FIGS. 6A to 6C. In this regard, FIG. 8 shows the first transistor T1 and the second transistor T2 among the transistors of the pixel driving circuit unit PC.

A buffer layer 201 may be disposed between the substrate 100 and the pixel driving circuit unit PC and prevent penetration of foreign materials into the transistors. The buffer layer 201 may include an inorganic insulating material, such as silicon oxide, silicon nitride, and silicon oxynitride, and may include a single layer or a multi-layer, each including the inorganic insulating material stated above.

The first transistor T1 may include a first semiconductor layer Act1 and a first gate electrode GE1. A source area and a drain area of the first semiconductor layer Act1 may be electrically connected to a first source electrode SE1 and/or a first drain electrode DE1, respectively. The second transistor T2 may include a second semiconductor layer Act2 and a second gate electrode GE2. A source area and a drain area of the second semiconductor layer Act2 may be electrically connected to a second source electrode SE2 and/or a second drain electrode DE2, respectively.

FIG. 8 illustrates a top-gate type in which the first and second gate electrodes GE1 and GE2 are disposed on the first and second semiconductor layers Act1 and Act2, respectively, with a gate insulating layer 203 therebetween, but according to another embodiment, the first and second transistors T1 and T2 may each be a bottom-gate type.

In an embodiment, each of the first and second semiconductor layers Act1 and Act2 may include polysilicon. In an embodiment, each of the first and second semiconductor layers Act1 and Act2 may include amorphous silicon, an oxide semiconductor, an organic semiconductor, or the like. Each of the first and second gate electrodes GE1 and GE2 may include a low-resistance metal material. Each of the first and second gate electrodes GE1 and GE2 may include a conductive material including molybdenum (Mo), aluminum (Al), copper (Cu), titanium (Ti), or the like, and may include a multi-layer or a single layer, each including the material stated above.

The gate insulating layer 203 may include an inorganic insulating material, such as silicon oxide, silicon nitride, and silicon oxynitride, and may include a single layer or a multi-layer, each including the material stated above.

The storage capacitor Cst may include the first electrode CE1 and the second electrode CE2, which overlap each other with a first interlayer insulating layer 205 therebetween. In an embodiment, the storage capacitor Cst may overlap the first transistor T1. In this regard, FIG. 8 shows that the first gate electrode GE1 of the first transistor T1 is the first electrode CE1 of the storage capacitor Cst. In another embodiment, the storage capacitor Cst may not overlap the first transistor T1. The storage capacitor Cst may be covered by a second interlayer insulating layer 207. The second electrode CE2 of the storage capacitor Cst may include a conductive material including Mo, Al, Cu, Ti, or the like, and may include a multi-layer or a single layer, each including the above-mentioned material.

The first and second source electrodes SE1 and SE2 and the first and second drain electrodes DE1 and DE2 may be disposed on the same layer, for example, on the second interlayer insulating layer 207, and may include the same material. The first and second source electrodes SE1 and SE2 and the first and second drain electrodes DE1 and DE2 may each include a conductive material including Mo, Al, Cu, Ti, or the like, and may include a multi-layer or a single layer, each including the above material.

Each of the first interlayer insulating layer 205 and the second interlayer insulating layer 207 may include an inorganic insulating material, such as silicon oxide, silicon nitride, and silicon oxynitride, and may include a single layer or a multi-layer, each including the material stated above. The first and second transistors T1 and T2 and the storage capacitor Cst may be covered with a first organic insulating layer 209.

A second organic insulating layer 211 and a third organic insulating layer 213 may be sequentially disposed on the first organic insulating layer 209. Each of the first organic insulating layer 209, the second organic insulating layer 211, and the third organic insulating layer 213 may include an organic insulating material. The organic insulating material may include a general commercial polymer such as poly(methyl methacrylate) (PMMA) or polystyrene (PS), a polymer derivative having a phenol group, an acrylic polymer, an imide polymer, an aryl ether polymer, an amide polymer, a fluorine polymer, a p-xylene polymer, a vinyl alcohol polymer, and a mixture thereof.

The second voltage line VSSL may be disposed on the second organic insulating layer 211. Although not illustrated in the drawing, the first voltage line VDDL (refer to FIGS. 6A to 6C) may be disposed on the first organic insulating layer 209 or the second organic insulating layer 211.

The first electrode pad 241 may be disposed on the third organic insulating layer 213. The first electrode pad 241 may be connected to a second contact metal CM2 through the first contact hole CNT1 in the third organic insulating layer 213, and the second contact metal CM2 may be connected to a first contact metal CM1 through a third contact hole CNT3 in the second organic insulating layer 211. FIG. 8 illustrates that the first electrode pad 241 is electrically connected to the first transistor T1 through the first and second contact metals CM1 and CM2, but the disclosure is not limited thereto. As described above with reference to FIGS. 6A to 6C, the pixel driving circuit unit PC may further include the sixth transistor T6 (refer to FIGS. 6B and 6C), and in this case, the first electrode pad 241 may be electrically connected to the sixth transistor T6 (refer to FIGS. 6B and 6C) through the first and second contact metals CM1 and CM2. The sixth transistor T6 (refer to FIGS. 6B and 6C) may have a structure substantially the same as the structure of the first transistor T1.

The second electrode pad 242 may be disposed on the same layer as the first electrode pad 241, for example, on the third organic insulating layer 213. As described above with reference to FIG. 7 and as showed in FIG. 8, the second electrode pad 242 (e.g., first and second connection portions 242-4 and 242-5) may be electrically connected to the second voltage line VSSL through the second contact hole CNT2 in the third organic insulating layer 213.

The light-emitting diode 230 may be an inorganic light-emitting diode. For example, the light-emitting diode 230 may include a first semiconductor layer 231, a second semiconductor layer 232, an intermediate layer 233 between the first semiconductor layer 231 and the second semiconductor layer 232. a first electrode 235 electrically connected to the first semiconductor layer 231, and a second electrode 238 electrically connected to the second semiconductor layer 232.

The first semiconductor layer 231 may include, for example, a p-type semiconductor layer. The p-type semiconductor layer is a semiconductor material with a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with a p-type dopant such as Mg, Zn, Ca, Sr, Ba, or the like.

The second semiconductor layer 232 may include, for example, an n-type semiconductor layer. The n-type semiconductor layer is a semiconductor material having a composition formula of InₓAl_{y}Ga_{1-x-y}N (0≤x≤1, 0≤y≤1, 0≤x+y≤1), which may, for example, be selected from among GaN, AlN, AlGaN, InGaN, InN, InAlGaN, AlInN, or the like, and may be doped with an n-type dopant such as Si, Ge, Sn, or the like.

The intermediate layer 233 is a region where electrons and holes are recombined. As the electrons and holes are recombined, the intermediate layer 233 may transition to a low energy level and generate light having a corresponding wavelength. For example, the intermediate layer 233 may be formed by including a semiconductor material having a composition formula of InₓAl_{y}Ga_{1-x-y}N (0≤x≤1, 0≤y≤1, 0≤x+y≤1), and may be formed as a single-quantum well structure or a multi-quantum well (“MQW”) structure. In addition, the intermediate layer 233 may also include a quantum wire structure or a quantum dot structure.

FIG. 8 illustrates that the first semiconductor layer 231 includes a p-type semiconductor layer, and the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

The first electrode 235 and the second electrode 238 of the light-emitting diode 230 may be electrically connected to the first electrode pad 241 and the second electrode pad 242 through a bump metal 250, respectively.

As the light-emitting diode 230 is formed by disposing the bump metal 250 on each of the first electrode pad 241 and the second electrode pad 242 and then disposing the light-emitting diode 230 by applying certain heat and certain pressure, the first electrode pad 241 and the second electrode pad 242 may be electrically connected to the light-emitting diode 230. For example, the light-emitting diode 230 may be electrically connected to the first electrode pad 241 through a first bump metal 250A between the light-emitting diode 230 and the first electrode pad 241. The light-emitting diode 230 may be electrically connected to the second electrode pad 242 through a second bump metal 250B between the light-emitting diode 230 and the second electrode pad 242.

Referring to FIGS. 7 and 8, some of the bump metals 250 may be disposed on corresponding electrode pads, respectively. The first bump metal 250A may be disposed on each of the corresponding the first-1 electrode pad 241-1, the first-2 electrode pad 241-2, and the first-3 electrode pad 241-3. That is, the first bump metals 250A connected to the first-1 electrode pad 241-1, the first-2 electrode pad 241-2, and the first-3 electrode pad 241-3, respectively, may not be electrically connected to each other. The planar shape of the first bump metal 250A is substantially identical to the planar shape of the first electrode pad 241. For example, when viewed in a direction perpendicular to an upper surface of the substrate 100, the shape of the first bump metal 250A on the first-1 electrode pad 241-1 is the same as the shape of the first-1 electrode pad 241-1. Likewise, the shape of the first bump metal 250A on the first-2 electrode pad 241-2 is the same as the shape of the first-2 electrode pad 241-2, and the shape of the first bump metal 250A on the first-3 electrode pad 241-3 is the same as the shape of the first-3 electrode pad 241-3. The second bump metal 250B may be disposed on the second electrode pad 242, for example, first to third portions 242-1, 242-2, and 242-3, and first and second connection portions 242-4 and 242-5. That is, the second bump metal 250B may be commonly electrically connected to the first to third portions 242-1, 242-2, and 242-3, and first and second connection portions 242-4 and 242-5. The planar shape of the second bump metal 250B is substantially identical to the planar shape of the second electrode pad 242. For example, when viewed in a direction perpendicular to an upper surface of the substrate 100, the shape of the second bump metal 250B is the same as the shape of the second electrode pad 242. The bump metal 250 may include a metal, such as gold (Au), nickel (Ni), or indium (In).

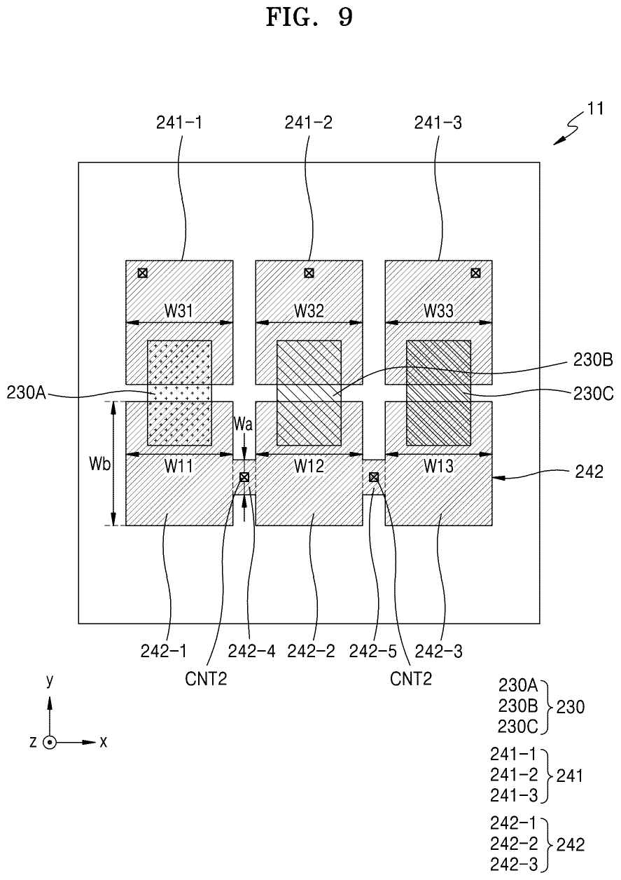

FIG. 9 is a plan view showing excerpts of the first and second electrode pads 241 and 242 and the light-emitting diodes 230, which are disposed in the first island portion 11 of a display device according to an embodiment.

The first and second electrode pads 241 and 242 shown in FIG. 9 and the light-emitting diodes 230 are as described above with reference to FIGS. 7 and 8. The first electrode pads 241, for example, the first-1 to first-3 electrode pads 241-1, 241-2, and 241-3, may be disposed to be spaced apart from each other in the first direction (for example, the x direction or the −x direction). The second electrode pad 242 may be spaced apart from the first electrode pads 241 in a direction crossing the arrangement direction of the first electrode pads 241 (for example, the second direction). The second electrode pad 242 may include the first to third portions 242-1, and the first and second connection portions 242-4 and 242-5.

The first light-emitting diode 230A may be electrically connected to the first-1 electrode pad 241-1 and the first portion 242-1 of the second electrode pad 242, which is adjacent to the first-1 electrode pad 241-1 in the second direction (for example, the y direction or the −y direction). The second light-emitting diode 230B may be electrically connected to the first-2 electrode pad 241-2 and the second portion 242-2 of the second electrode pad 242, which is adjacent to the first-2 electrode pad 241-2 in the second direction (for example, the y direction or the −y direction). The third light-emitting diode 230C may be electrically connected to the first-3 electrode pad 241-3 and the third portion 242-3 of the second electrode pad 242, which is adjacent to the first-3 electrode pad 241-3 in the second direction (for example, the y direction or the-y direction).

A width Wa of the first connection portion 242-4, which connects the first portion 242-1 and the second portion 242-2 of the second electrode pad 242 to each other, in the second direction may be less than a width Wb of each of the first portion 242-1 and the second portion 242-2 in the second direction. A width Wa of the second connection portion 242-5, which connects the second portion 242-2 and the third portion 242-3 of the second electrode pad 242 to each other, in the second direction may be less than a width Wb of each of the second portion 242-2 and the third portion 242-3 in the second direction.

As a comparative example of the disclosure, in a case in which the second electrode pad 242 has a quadrangular shape with a constant width (for example, a square shape or a rectangular shape), in a process of electrically connecting a light-emitting element to the first and second electrode pads 241 and 242 by using the bump metal 250 (refer to FIG. 8), a phenomenon in which the second bump metal 250B (refer to FIG. 8) on the second electrode pad 242, which has a relatively large area, is pushed may occur. For example, in a process of applying heat and pressure to dispose the light-emitting diode 230 after disposing the bump metal 250 on the first and second electrode pads 241 and 242, a problem may be caused in which the second bump metal 250B on the second electrode pad 242 deviates from the boundary of the second electrode pad 242 and moves to the periphery of the second electrode pad 242 and/or the uniformity of the thickness of the bump metal 250 is reduced. However, as an embodiment of the disclosure, when the second electrode pad 242 includes portions having a relatively small width (for example, the first connection portion 242-4 and the second connection portion 242-5) and portions having a relatively large width (for example, the first to third portions 242-1, 242-2, and 242-3), the phenomenon in which the bump metal 250 is pushed as described above may be reduced or prevented.

The problem in which the bump metal 250 is pushed and/or the uniformity of the thickness of the bump metal 250 is reduced as described above may be effectively prevented by disposing a connection point (e.g., the second contact hole CNT2) between the second electrode pad 242 and the second voltage line VSSL (refer to FIG. 7), which is a common voltage line, to correspond to the first connection portion 242-4 and/or the second connection portion 242-5. The flatness of an upper surface of the first connection portion 242-4 and/or the second connection portion 242-5 corresponding to the connection point (e.g., the second contact hole CNT2) between the second electrode pad 242 and the second voltage line VSSL (refer to FIG. 7), which is a common voltage line, may be relatively lower than the flatness of upper surfaces of the first to third portions 242-1,242-2, and 242-3. The structure described above may reduce the uniformity of the thickness of the bump metal 250 and cause the bump metal 250 to be pushed, but in an embodiment of the disclosure, the above problem may be prevented by allowing the position of the second contact hole CNT2 to overlap the first connection portion 242-4 and/or the second connection portion 242-5, which has a relatively narrow width, as described above.

In an embodiment, the first to third portions 242-1, 242-2, and 242-3 of the second electrode pad 242 have widths W11, W12, and W13 in the first direction, respectively, but the widths W11, W12, and W13 as described above may be constant in the second direction. In an embodiment, the first-1 to first-3 electrode pads 241-1, 241-2, and 241-3 have widths W31, W32, and W33 in the first direction, respectively, but the widths W31, W32, and W33 as described above may be constant in the second direction.

In an embodiment, the widths W11, W12, and W13 of the respective first to third portions 242-1, 242-2, and 242-3 of the second electrode pad 242 in the first direction may be equal to each other. In an embodiment, the widths W31, W32, and W33 of the respective first-1 to first-3 electrode pads 241-1, 241-2, and 241-3 may be equal to each other. In an embodiment, each of the first electrode pads 241 may have substantially the same width as a portion of an adjacent second electrode pad 242. For example, the width W11 of the first portion 242-1 of the second electrode pad 242 in the first direction may be equal to the width W31 of the first-1 electrode pad 241-1 in the first direction. The width W12 of the second portion 242-2 of the second electrode pad 242 in the first direction may be equal to the width W32 of the first-2 electrode pad 241-2 in the first direction. The width W13 of the third portion 242-3 of the second electrode pad 242 in the first direction may be equal to the width W33 of the first-3 electrode pad 241-3 in the first direction.

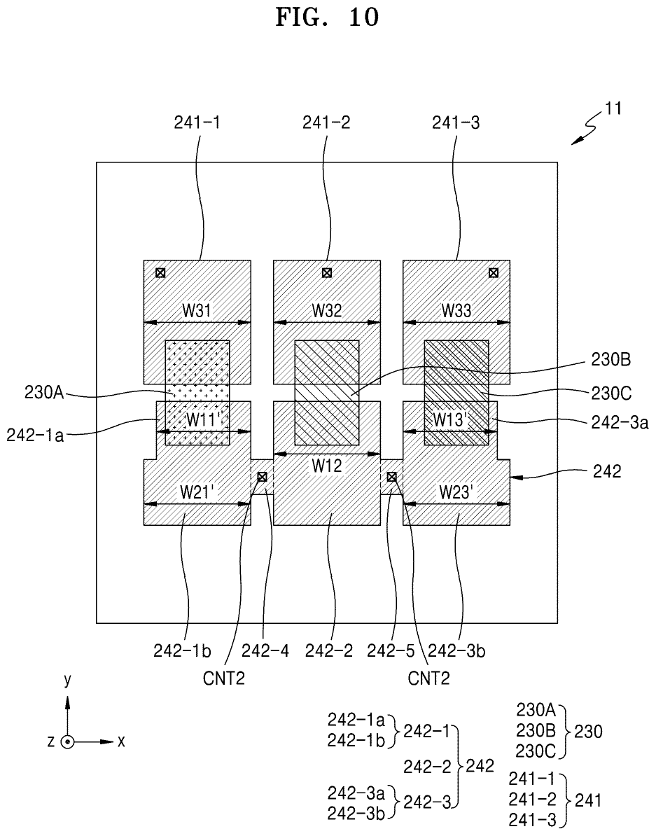

FIG. 9 illustrates that each of the first to third portions 242-1, 242-2, and 242-3 of the second electrode pad 242 has an approximate rectangular shape having uniform widths in the first and second directions, but the disclosure is not limited thereto. As shown in FIGS. 10 to 12, the first to third portions 242-1, 242-2, and 242-3 of the second electrode pad 242 may not have a uniform width in the second direction.

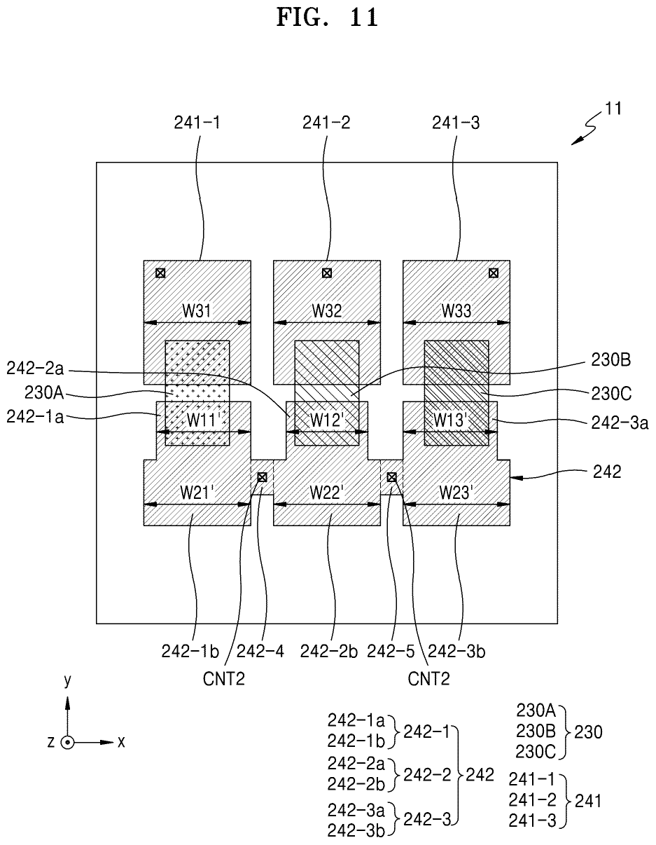

FIGS. 10 and 11 are plan views each showing excerpts of the first and second electrode pads 241 and 242 and the light-emitting diodes 230, which are disposed in the first island portion 11 of the display device 1 according to an embodiment. The first and second electrode pads 241 and 242 shown in FIGS. 10 and 11 are substantially the same as the first and second electrode pads 241 and 242 described above with reference to FIGS. 7 to 9, but the widths of the first to third portions 242-1, 242-2, and 242-3 of the second electrode pad 242 are different from the structure of the second electrode pad 242 shown in FIGS. 7 and 9. Hereinafter, for convenience of explanation, the differences are mainly described.

At least one selected from among the first to third portions 242-1, 242-2, and 242-3 of the second electrode pad 242 may include portions having different widths in the first direction (e.g., the x direction or the-x direction).

In an embodiment, as shown in FIG. 10, for example, each of the first portion 242-1 and the third portion 242-3 of the second electrode pad 242 may include portions having different widths in the first direction (e.g., the x direction or the-x direction).

The first portion 242-1 may include a first-1 portion 242-1a relatively adjacent to the first-1 electrode pad 241-1 and a first-2 portion 242-1b relatively far from the first-1 electrode pad 241-1. A width W11′ of the first-1 portion 242-1a in the first direction (e.g., the x direction or the −x direction) may be less than a width W21′ of the first-2 portion 242-1b in the first direction (e.g., the x direction or the-x direction). The width W11′ of the first-1 portion 242-1a in the first direction (e.g., the x direction or the-x direction) may be less than a width W31 of the first-1 electrode pad 241-1 in the first direction (e.g., the x direction or the −x direction).

The third portion 242-3 may include a third-1 portion 242-3a relatively adjacent to the first-3 electrode pad 241-3 and a third-2 portion 242-3b relatively far from the first-3 electrode pad 241-3. A width W13′ of the third-1 portion 242-3a in the first direction (e.g., the x direction or the −x direction) may be less than a width W23′ of the third-2 portion 242-3b in the first direction (e.g., the x direction or the −x direction). The width W13′ of the third-1 portion 242-3a in the first direction (e.g., the x direction or the-x direction) may be less than a width W33 of the first-3 electrode pad 241-3 in the first direction (e.g., the x direction or the −x direction).

FIG. 10 illustrates that two selected from among the first to third portions 242-1, 242-2, and 242-3 include portions having different widths in the first direction (e.g., the x direction or the −x direction), but the disclosure is not limited thereto. In an embodiment, as shown in FIG. 11, each of the first to third portions 242-1, 242-2, and 242-3 of the second electrode pad 242 may include portions having different widths in the first direction (e.g., the x direction or the-x direction).

Each of the first portion 242-1 and the third portion 242-3 of FIG. 11 has the same structure as that shown in FIG. 10. Similarly to the first portion 242-1 and the third portion 242-3, the second portion 242-2 may include a second-1 portion 242-2a relatively adjacent to the first-2 electrode pad 241-2 and a second-2 portion 242-2b relatively far from the first-2 electrode pad 241-2. A width W12′ of the second-1 portion 242-2a in the first direction (e.g., the x direction or the-x direction) may be less than a width W22′ of the second-2 portion 242-2b in the first direction (e.g., the x direction or the −x direction). The width W12′ of the second-1 portion 242-2a in the first direction (e.g., the x direction or the −x direction) may be less than a width W32 of the first-2 electrode pad 241-2 in the first direction (e.g., the x direction or the −x direction).

FIGS. 10 and 11 illustrate that two or three selected from among the first to third portions 242-1, 242-2, and 242-3 include portions having different widths in the first direction (e.g., the x direction or the −x direction), but the disclosure is not limited thereto. In another embodiment, any one selected from among the first to third portions 242-1, 242-2, and 242-3, for example, the second portion 242-2, may include portions having different widths in the first direction (e.g., the x direction or the −x direction), as shown in FIG. 11, and the first portion 242-1 and the third portion 242-3 may have constant widths W11 and W13 in the second direction, respectively, as shown in FIG. 9.

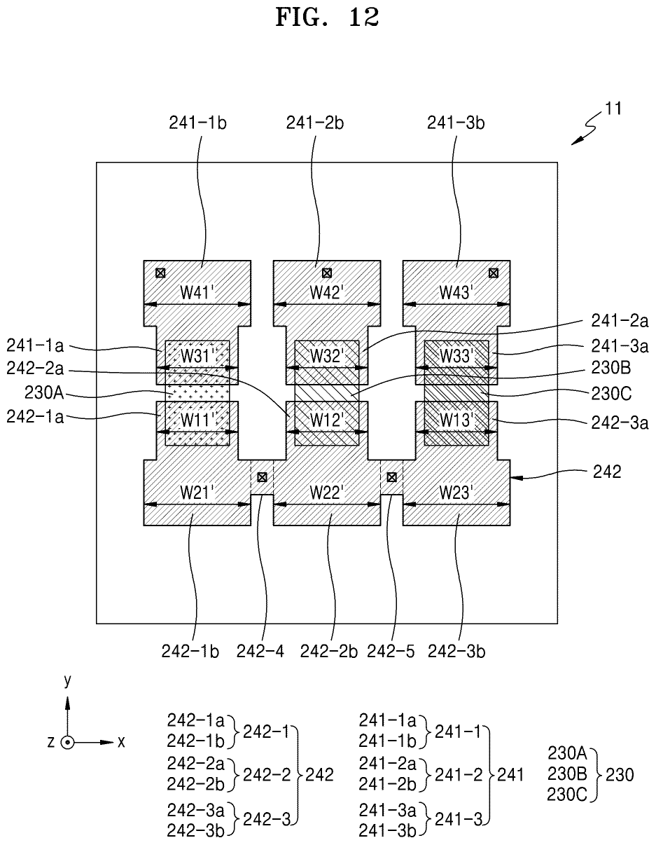

FIG. 12 is a plan view showing excerpts of the first and second electrode pads 241 and 242 and the light-emitting diodes 230, which are disposed in the first island portion 11 of the display device 1 according to an embodiment. The structure of the second electrode pad 242 shown in FIG. 12 is substantially the same as the structure of the second electrode pad 242 described above with reference to FIG. 11. In an embodiment of FIG. 12, it is shown that the first electrode pad 241 include portions having different widths in the first direction (e.g., the x direction or the −x direction). Hereinafter, for convenience of explanation, the differences between the structures of the first electrode pads 241 of FIGS. 11 and 12 are mainly described.

In an embodiment, the first-1 electrode pad 241-1 may include a first portion 241-1a relatively adjacent to the second electrode pad 242 and a second portion 241-1b relatively far from the second electrode pad 242. A width W31′ of the first portion 241-1a of the first-1 electrode pad 241-1 in the first direction (e.g., the x direction or the −x direction) may be less than a width W41′ of the second portion 241-1b of the first-1 electrode pad 241-1 in the first direction (e.g., the x direction or the −x direction). The width W31′ of the first portion 241-1a of the first-1 electrode pad 241-1 in the first direction (e.g., the x direction or the −x direction) may be equal to the width W11′ of the first-1 portion 242-1a of the first portion 242-1 of the second electrode pad 242 in the first direction (e.g., the x direction or the −x direction). The first light-emitting diode 230A may overlap the first portion 241-1a of the first-1 electrode pad 241-1 and the first-1 portion 242-1a of the first portion 242-1 of the second electrode pad 242.

The first-2 electrode pad 241-2 may include a first portion 241-2a relatively adjacent to the second electrode pad 242 and a second portion 241-2b relatively far from the second electrode pad 242. A width W32′ of the first portion 241-2a of the first-2 electrode pad 241-2 in the first direction (e.g., the x direction or the-x direction) may be less than a width W42′ of the second portion 241-2b of the first-2 electrode pad 241-2 in the first direction (e.g., the x direction or the −x direction). The width W32′ of the first portion 241-2a of the first-2 electrode pad 241-2 in the first direction (e.g., the x direction or the −x direction) may be equal to the width W12′ of the second-1 portion 242-2a of the second portion 242-2 of the second electrode pad 242 in the first direction (e.g., the x direction or the-x direction). The second light-emitting diode 230B may overlap the first portion 241-2a of the first-2 electrode pad 241-2 and the second-1 portion 242-2a of the second portion 242-2 of the second electrode pad 242.

The first-3 electrode pad 241-3 may include a first portion 241-3a relatively adjacent to the second electrode pad 242 and a second portion 241-3b relatively far from the second electrode pad 242. A width W33′ of the first portion 241-3a of the first-3 electrode pad 241-3 in the first direction (e.g., the x direction or the −x direction) may be less than a width W43′ of the second portion 241-3b of the first-3 electrode pad 241-3 in the first direction (e.g., the x direction or the-x direction). The width W33′ of the first portion 241-3a of the first-3 electrode pad 241-3 in the first direction (e.g., the x direction or the −x direction) may be equal to the width W13′ of the third-1 portion 242-3a of the third portion 242-3 of the second electrode pad 242 in the first direction (e.g., the x direction or the −x direction). The third light-emitting diode 230C may overlap the first portion 241-3a of the first-3 electrode pad 241-3 and the third-1 portion 242-3a of the third portion 242-3 of the second electrode pad 242.

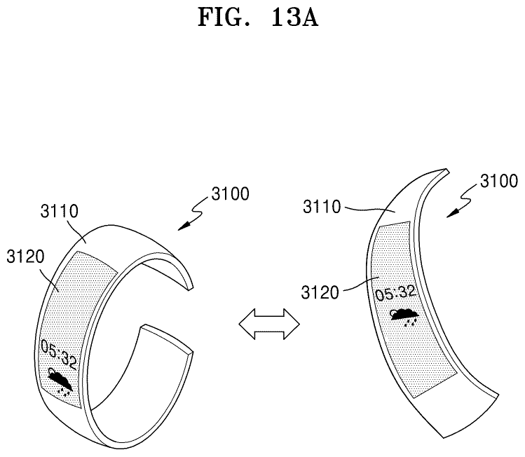

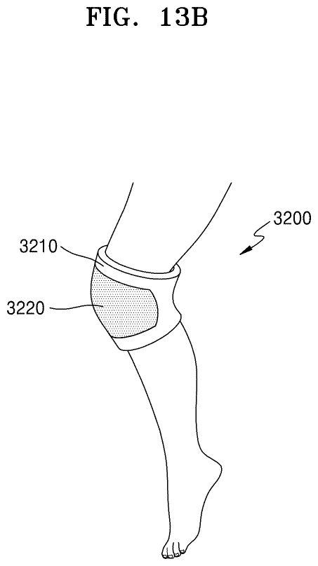

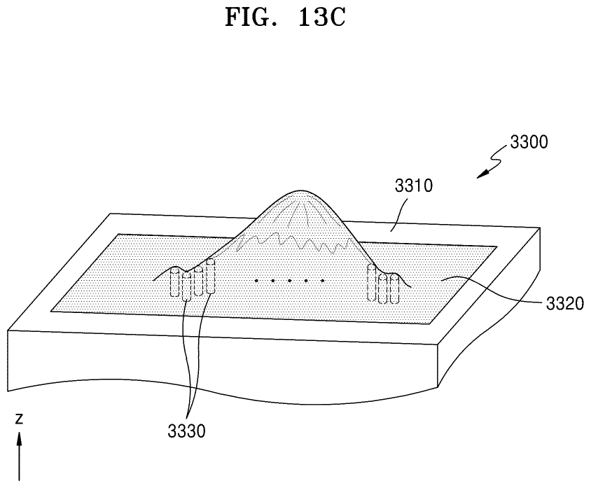

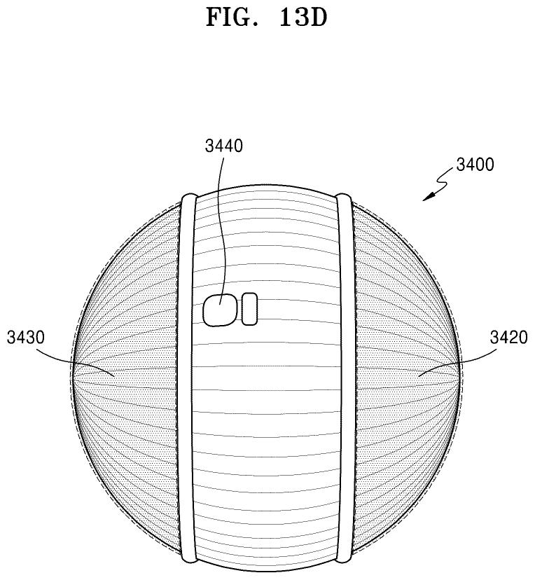

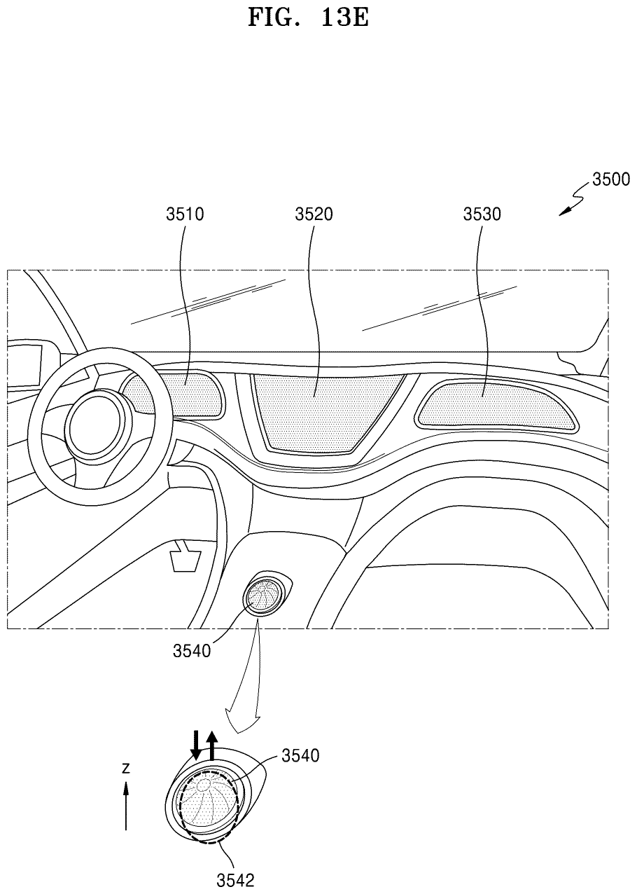

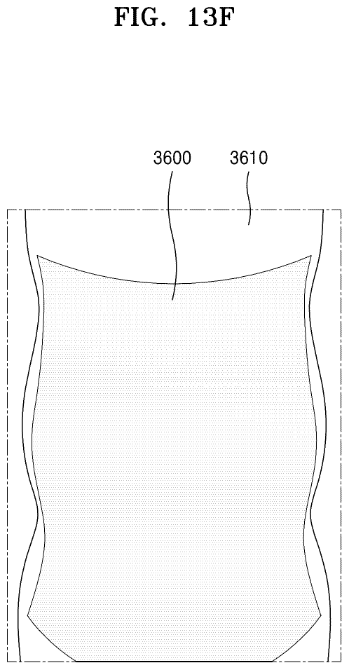

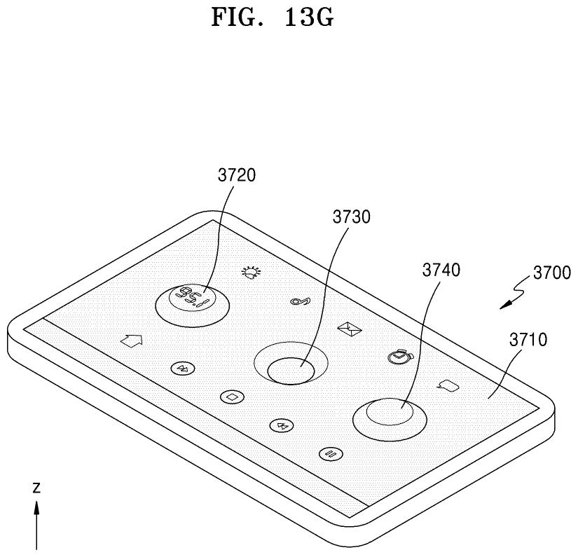

FIGS. 13A to 13G are schematic perspective views showing the embodiments of an electronic device including a display apparatus, respectively.

Referring to FIG. 13A, a display device according to an embodiment may be used in a wearable electronic apparatus 3100 which may be worn on a part of a user's body. The wearable electronic apparatus 3100 may include a body portion 3110 and a display portion 3120 provided in the body portion 3110. The display device according to embodiments may be used as the display portion 3120 of the wearable electronic apparatus 3100. As shown in FIG. 13A, the wearable electronic apparatus 3100 may be transformable. In an embodiment, the wearable electronic apparatus 3100 may be used as a smart watch or a smartphone depending on the user's choice.

FIG. 13B shows a medical electronic apparatus 3200. In an embodiment, the medical electronic apparatus 3200 may include a body portion 3210 and a light-emitting portion 3220. The display device according to embodiments may be used as the light-emitting portion 3220 of the medical electronic apparatus 3200. The light-emitting portion 3220 may emit light of a certain wavelength band (e.g., infrared light, visible light ray, or the like) to the body of a patient. In an embodiment, the body portion 3210 may include a stretchable fiber material and may have a structure that the light-emitting portion 3220 may be worn on the user's body.

FIG. 13C shows an educational electronic apparatus 3300. In an embodiment, the educational electronic apparatus 3300 may include a display portion 3320 provided in a frame 3310. The display portion 3320 may use the display device according to embodiments. The display portion 3320 may provide images, such as a sea with waves, a mountain covered with snow, or a volcano with flowing lava, and in this case, the display portion 3320 may extend in a height direction (e.g., a z direction) by reflecting the height of the waves, the mountain, or the volcano. In some embodiments, a portion of the display portion 3320 may three-dimensionally show the movement of lava by sequentially changing the height along a direction in which the lava flows. The educational electronic apparatus 3300 may include a plurality of strokes 3330 disposed below the display portion 3320, for example, below the rear surface of the display portion 3320, so that the display portion 3320 may be stretched in the height direction. While the strokes 3330 move along a third direction (e.g., a z direction or a −z direction), an image displayed on the display portion 3320 may be implemented to have a three-dimensional height. In an embodiment, the strokes 3330 may also provide haptic information. FIG. 13 shows the educational electronic apparatus 3300, but the use is not limited as long as the apparatus provides certain image information.

As shown in FIGS. 13A to 13C, an electronic apparatus of which the shapes may be variable is described as the electronic apparatus, but the disclosure is not limited thereto. As to be described below, the display device according to embodiments may be used in an electronic apparatus in which a portion capable of displaying images (e.g., a screen) is fixed.

FIG. 13D shows a robot 3400 as an electronic apparatus according to an embodiment. The robot 3400 may recognize movement or objects by using a camera unit 3440 and may display certain images through display portions 3420 and 3430. In some embodiments, as described above, because the display device according to an embodiment may be stretched in various directions, the display device may be assembled into a body frame having a hemispherical shape, and accordingly, the robot 3400 may include the display portions 3420 and 3430 having hemispherical shapes.

FIG. 13E shows a vehicle display device 3500 as an electronic apparatus according to an embodiment. The vehicle display device 3500 may include a cluster 3510, a center information display (CID) 3520, and/or a co-driver display. Because the display device according to the embodiment may be stretched in various directions, the display device may be used in the cluster 3510, the CID 3520, and/or the co-driver display regardless of the shape of the internal frame of the vehicle.

FIG. 13E shows that the cluster 3510, the CID 3520, and the co-driver display are separated from each other, but the disclosure is not limited thereto. In another embodiment, two or more selected from the cluster 3510, the CID 3520, and the co-driver display may be integrally connected to each other.

In some embodiments, the vehicle display device 3500 may include a button 3540 that may display a certain image. Referring to the enlarged view of FIG. 13E, the button 3540 having a hemispherical shape may include an object 3542 that provides the feeling of using while moving in the z direction or the-z direction, and a display device disposed on the object 3542. In some embodiments, when the object 3542 has a three-dimensionally rounded surface, the display device may also have a three-dimensionally rounded surface.

FIG. 13F shows that an electronic apparatus according to an embodiment is an advertising or exhibiting electronic apparatus 3600. In some embodiments, the advertising or exhibiting electronic apparatus 3600 may be installed on a fixed structure 3610, such as a wall or pillar. When the structure 3610 includes an uneven surface as shown in FIG. 13F, the advertising or exhibiting electronic apparatus 3600 may be disposed along the uneven surface of the structure 3610. In some embodiments, the advertising or exhibiting electronic apparatus 3600 may be installed on the structure 3610 by using a heat shrink film or the like.

FIG. 13G shows that an electronic apparatus according to an embodiment is a controller 3700. The controller 3700 may include an image-type button. For example, the controller 3700 may include first to third button areas 3720, 3730, and 3740 in which a partial area of a display portion 3710 protrudes in a z direction or a −z direction (or is depressed in the z direction). In some embodiments, the first and third button areas 3720 and 3740 may protrude in the z direction, and the second button area 3730 may protrude in the-z direction (or may be depressed in the z direction).

According to an embodiment, a display device that may stably maintain electrical connection of a light-emitting element and an electronic apparatus including the display device may be provided.

However, these effects are exemplary, and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a first-1 electrode pad and a first-2 electrode pad, spaced apart from each other in a first direction;
a second electrode pad spaced apart from the first-1 electrode pad and the first-2 electrode pad in a second direction crossing the first direction, the second electrode pad comprising:
a first portion;
a second portion adjacent to the first portion in the first direction; and
a connection portion connecting the first portion and the second portion to each other;
a first light-emitting element electrically connected to the first-1 electrode pad through a first bump metal and electrically connected to the first portion of the second electrode pad through a second bump metal; and
a second light-emitting element electrically connected to the first-2 electrode pad through a third bump metal and electrically connected to the second portion of the second electrode pad through the second bump metal,
wherein a width of the connection portion of the second electrode pad in the second direction is less than a width of the first portion of the second electrode pad in the second direction.

2. The display device of claim 1, further comprising:
a common voltage line electrically connected to the second electrode pad; and
an insulating layer between the second electrode pad and the common voltage line,
wherein the connection portion of the second electrode pad is electrically connected to the common voltage line through a contact hole in the insulating layer.

3. The display device of claim 1, wherein
a width of the first portion of the second electrode pad in the first direction is substantially equal to a width of the first-1 electrode pad in the first direction.

4. The display device of claim 1, wherein the first portion of the second electrode pad comprises:
a first-1 portion relatively adjacent to the first-1 electrode pad; and
a first-2 portion relatively far from the first-1 electrode pad, and
a width of the first-1 portion in the first direction is less than a width of the first-2 portion in the first direction.

5. The display device of claim 4, wherein a width of the second portion of the second electrode pad in the first direction is greater than the width of the first-1 portion of the first portion of the second electrode pad in the first direction.

6. The display device of claim 4, wherein the second portion of the second electrode pad comprises:
a second-1 portion relatively adjacent to the first-2 electrode pad; and
a second-2 portion relatively far from the first-2 electrode pad, and
a width of the second-1 portion in the first direction is less than a width of the second-2 portion in the first direction.

7. The display device of claim 4, wherein a width of a first portion of the first-1 electrode pad, which is relatively adjacent to the first portion of the second electrode pad, in the first direction is less than a width of a second portion of the first-1 electrode pad, which is relatively far from the first portion of the second electrode pad, in the first direction.

8. The display device of claim 7, wherein the width of the first portion of the first-1 electrode pad is substantially equal to the width of the first-1 portion of the first portion of the second electrode pad in the first direction.

9. The display device of claim 1, wherein the second bump metal comprises gold, nickel, or indium.

10. The display device of claim 7, wherein each of the first bump metal and the third bump metal comprises a same material as the second bump metal.

11. A display device comprising a display area and a non-display area outside the display area, the display device comprising:
a first island portion positioned in the display area;
a first bridge portion connecting the first island portion and another first island portion adjacent to the first island portion to each other;
first electrode pads disposed in the first island portion and spaced apart from each other in a first direction;
a second electrode pad disposed in the first island portion and spaced apart from the first electrode pads in a second direction crossing the first direction, the second electrode pad comprising:
a first portion, a second portion, and a third portion, spaced apart from each other in the first direction;
a first connection portion connecting the first portion and the second portion to each other; and
a second connection portion connecting the second portion and the third portion to each other; and
light-emitting elements electrically connected to the first electrode pads, respectively, and the first to third portions of the second electrode pad, respectively,
wherein a width of the first connection portion in the second direction and a width of the second connection portion in the second direction are each less than a width of the second portion of the second electrode pad in the second direction.

12. The display device of claim 11, further comprising a common voltage line electrically connected to the second electrode pad,
wherein a connection point of the second electrode pad and the common voltage line corresponds to at least one of the first connection portion and the second connection portion of the second electrode pad.

13. The display device of claim 11, wherein the first portion of the second electrode pad comprises:
a first-1 portion relatively adjacent to the first electrode pads; and
a first-2 portion relatively far from the first electrode pads, and
a width of the first-1 portion in the first direction is less than a width of the first-2 portion in the first direction.

14. The display device of claim 13, wherein a width of the second portion of the second electrode pad in the first direction is greater than the width of the first-1 portion of the first portion of the second electrode pad in the first direction.

15. The display device of claim 13, wherein the second portion of the second electrode pad comprises:
a second-1 portion relatively adjacent to the first electrode pads; and
a second-2 portion relatively far from the first electrode pads, and
a width of the second-1 portion in the first direction is less than a width of the second-2 portion in the first direction.

16. The display device of claim 13, wherein a first electrode pad among the first electrode pads, which is adjacent to the first portion of the second electrode pad, comprises a portion relatively adjacent to the first portion of the second electrode pad and a portion relatively far from the first portion of the second electrode pad, and
a width of the portion relatively adjacent to the first portion of the second electrode pad in the first direction is less than a width of the portion relatively far from the first portion of the second electrode pad in the first direction.

17. The display device of claim 11, wherein the second bump metal comprises gold, nickel, or indium.

18. An electronic apparatus comprising a display device, the display device comprising:
a first-1 electrode pad and a first-2 electrode pad, spaced apart from each other in a first direction;
a second electrode pad spaced apart from the first-1 electrode pad and the first-2 electrode pad in a second direction crossing the first direction and comprising a first portion, a second portion adjacent to the first portion in the first direction, and a connection portion connecting the first portion and the second portion to each other;
a first light-emitting element electrically connected to the first-1 electrode pad through a first bump metal and electrically connected to the first portion of the second electrode pad through a second bump metal; and
a second light-emitting element electrically connected to the first-2 electrode pad through a third bump metal and electrically connected to the second portion of the second electrode pad through the second bump metal,
wherein a width of the connection portion of the second electrode pad in the second direction is less than a width of the first portion of the second electrode pad in the second direction.

19. The electronic apparatus of claim 18, wherein the display device further comprises:
a common voltage line electrically connected to the second electrode pad; and
an insulating layer between the second electrode pad and the common voltage line, and
the connection portion of the second electrode pad is electrically connected to the common voltage line through a contact hole in the insulating layer.

20. The electronic apparatus of claim 18, wherein each of the first bump metal, the second bump metal, and the third bump metal comprises gold, nickel, or indium.
